(19) United States
(12) Patent Application Publication
(10) Pub. No.: US 2026/0178800 A1
(43) Pub. Date: Jun. 25, 2026

(54) THREE-PHASE FLOW AND HEAT TRANSFER COUPLED SIMULATION METHOD AND SYSTEM BASED ON IBM-VOSET-DEM

(71) Applicant: Jiangsu University, Jiangsu (CN)

(72) Inventors: Fei DONG, Jiangsu (CN); Hekun JIA, Jiangsu (CN); Bifeng YIN, Jiangsu (CN); Jie NI, Jiangsu (CN)

(73) Assignee: Jiangsu University, Jiangsu (CN)

(21) Appl. No.: 18/856,067

(22) PCT Filed: Jan. 10, 2024
(86) PCT No.: PCT/CN2024/071505

§ 371 Date: Oct. 11, 2024

(30) Foreign Application Priority Data
Oct. 8, 2023 (CN) 202311291754.2

(51) Int. Cl. G06F 30/28

(52) U.S. Cl. CPC G06F 30/28

(57) ABSTRACT

The present disclosure provides a three-phase flow and heat transfer coupled simulation method. The method includes: initializing parameters; reconstructing a liquid-liquid interface; determining a fluid volume fraction at an (n+1)-th time; determining a boundary grid; and determining a signed distance function of a grid cell at an n-th time; determining an interface curvature of the interface grid cell; determining abrupt physical quantities at a smooth interface; determining a surface tension of the interface; determining an intermediate fluid velocity; acquiring the fluid volume fraction and the intermediate velocity in each grid cell in the computational domain; determining a particle velocity; determining a displacement of a p-th solid particle at the (n+1)-th time and a solid volume fraction in the grid cell at the (n+1)-th time; determining a final velocity of the computational domain at the (n+1)-th time; and solving a temperature and an interface heat flux density.

### TECHNICAL FIELD

The present disclosure relates to the field of fluid mechanics simulation, and in particular to a three-phase flow and heat transfer coupled simulation method and system based on immersed boundary method-volume of fluid and level set-discrete element method (IBM-VOSET-DEM).

### BACKGROUND

The changeable flow and heat transfer issues of two-phase flow interfaces with solid particles are widely present in the field of energy and chemical engineering. The three-phase flow and heat transfer issue involves very complex interactions: liquid-liquid interactions, solid-liquid interactions, and solid-solid interactions. Experimental research is greatly limited and cannot acquire microscopic information on multiphase flow and heat transfer. Numerical simulation can precisely compensate for this deficiency and has become an important way to study multiphase flow and heat transfer.

Regarding numerical simulations of multiphase flow and heat transfer, the volume of fluid (VOF) method, the level set (LS) method, and their coupled models (CLSVOF and VOSET) are commonly used to capture the two-phase interface for liquid-liquid flow. The multiphase flow models of particles usually regard the particles as a continuous phase, but they cannot accurately acquire the microscopic motion information of the particles and their effects on the fluid. The particles can also be regarded as a discrete phase, and their motion information is acquired through methods such as DPM and discrete cell method (DEM).

However, for three-phase systems, there are currently few mathematical models of flow and heat transfer that simultaneously consider liquid-liquid interactions, solid-liquid interactions, and solid-solid interactions.

### SUMMARY

To address the shortcomings of the prior art, the present disclosure provides a three-phase flow and heat transfer coupled simulation method and system based on IBM-VOSET-DEM. The present disclosure captures a liquid-liquid interface through the VOSET method, overcoming the disadvantages of LS and VOF methods. The LS method is likely to cause non-conservation of fluid mass in calculation, and the VOF method has a large error in interface curvature calculation and has a poor effect in acquiring nearby abrupt physical quantities of the smooth interface. The present disclosure uses the immersed boundary method (IBM) to acquire a solid particle interface, avoiding body-fitted grid generation at a particle boundary and thereby reducing the computational cost. The present disclosure can accurately acquire and track the microscopic motion information of a solid particle by calculating a solid collision force by a DEM soft ball model. The present disclosure adopts an interface heat flux density model, taking into account the conjugate heat transfer effect at a liquid-solid interface.

The present disclosure achieves the above technical objective through the following technical solutions.

A three-phase flow and heat transfer coupled simulation method based on IBM-VOSET-DEM includes the following steps:
S01: determining a computational domain, and dividing the computational domain into grids: determining a size of the computational domain, determining a number N of particles and a particle size D in the computational domain, where any of the grids in the computational domain is represented as (Nₓ, N_{y}), x∈[1, N₁], y∈[1, N₂]; and setting a calculation time step to Δt and a total number of time steps to Nₜ, where N₁ denotes a total number of the grids in a horizontal direction; and N₂ denotes a total number of the grids in a vertical direction;
S02: initializing parameters: determining a fluid velocity

$${u}_{f}^{0} ( x , y )$$

initial time, a fluid temperature

$${T}_{f}^{0} ( x , y )$$

in each grid cell at the initial time, and a fluid volume fraction F⁰(x, y) in each grid cell at the initial time; determining a center position (xₛ, yₛ) of each solid particle at the initial time, a solid velocity

$${u}_{s}^{0} ( x , y )$$

in each grid cell at the initial time, a solid temperature

$${T}_{s}^{0} ( x , y )$$

in each grid cell at the initial time, and a solid volume fraction

$${∅}_{s}^{0} ( x , y )$$

in each grid cell at the initial time; and determining all thermophysical parameters, including: a density ρ₁ of a first fluid, a density ρ₂ of a second fluid, a density ρₛ of the solid particle, a viscosity μ₁ of the first fluid, a viscosity μ₂ of the second fluid, a thermal conductivity coefficient λ₁ of the first fluid, a thermal conductivity coefficient λ₂ of the second fluid, and a thermal conductivity coefficient λₛ of the solid particle;
S03: reconstructing a liquid-liquid interface:
determining, if a fluid volume fraction Fⁿ(x, y)∈(0,1), that the grid cell (Nₓ, N_{y}) at an n-th time is a liquid-liquid interface grid; determining, if Fⁿ(x, y)=0, that the grid cell (Nₓ, N_{y}) at the n-th time is filled with the second fluid; and determining, if Fⁿ(x, y)=1, that the grid cell (Nₓ, N_{y}) at the n-th time is filled with the first fluid; and
reconstructing, if a grid (x, y) is a liquid-liquid interface grid, an interface shape for each grid cell at the n-th time through a particle line-segment interface calculation (PLIC) method;
S04: determining a fluid volume fraction at an (n+1)-th time:
acquiring, based on a velocity in the grid cell (Nₓ, N_{y}) at the n-th time and the fluid volume fraction Fⁿ(x, y) in the grid cell (Nₓ, N_{y}) at the n-th time, a fluid volume flowing into and out of the grid cell (Nₓ, N_{y}) within a time of Δt, and acquiring the fluid volume fraction Fⁿ⁺¹(x, y) in the grid cell at the (n+1)-th time;
S05: determining a boundary grid; and determining, if the grid (x, y) is a liquid-liquid interface grid, a signed distance function Øⁿ(x, y) of the grid cell (Nₓ, N_{y}) at the n-th time;
S06: determining an interface curvature k(x, y) of an interface grid cell (Nₓ, N_{y});
S07: determining abrupt physical quantities at a smooth interface: determining, by a Heaviside function, a nearby density and viscosity of the smooth interface of the grid cell (Nₓ, N_{y}) at the n-th time:
calculating a smooth density in the grid cell (Nₓ, N_{y}) at the n-th time as follows:

$$ρ ( {∅}^{n} ( x , y ) ) = {ρ}_{1} ( 1 - H ( {∅}^{n} ( x , y ) ) ) + {ρ}_{2} H ( {∅}^{n} ( x , y ) )$$

calculating a smooth viscosity in the grid cell (Nₓ, N_{y}) at the n-th time as follows:

$$μ ( {∅}^{n} ( x , y ) ) = {μ}_{1} ( 1 - H ( {∅}^{n} ( x , y ) ) ) + {μ}_{2} H ( {∅}^{n} ( x , y ) )$$

where, the Heaviside function H(Øⁿ) is expressed as follows:

$$H ( {∅}^{n} ( x , y ) ) = \{ \begin{matrix}0 & if {∅}^{n} ( x , y ) < - ϵ \\ \frac{1}{2} - [ 1 + \frac{{∅}^{n} ( x , y )}{ϵ} + \frac{1}{π} ( \frac{π {∅}^{n} ( x , y )}{ϵ} ) ] & if \vert {∅}^{n} ( x , y ) \vert \leq ϵ \\ 1 & if {∅}^{n} ( x , y ) > ϵ\end{matrix}$$

where, ∈ denotes a thickness of the smooth interface;
S08: determining a surface tension of an interface;
calculating the surface tension at the liquid-liquid interface; and specifically, calculating, by a continuous surface force model, a surface tension

$${F}_{s}^{n} ( x , y )$$

in the grid cell (Nₓ, N_{y}) at the n-th time as follows:

$${F}_{s}^{n} ( x , y ) = - σ k ( x , y ) δ ( {∅}^{n} ( x , y ) ) ∇ {∅}^{n} ( x , y )$$

where, σ denotes a surface tension coefficient, and

$$δ ( {∅}^{n} ( x , y ) ) = \frac{d H ( {∅}^{n} ( x , y ) )}{d {∅}^{n} ( x , y )} ;$$

if there is no interface, there is no surface tension; and the surface tension in the grid cell (Nₓ, N_{y}) at the n-th time is

$${F}_{s}^{n} ( x , y ) = 0 ;$$

S09: determining an intermediate fluid velocity

$${u}_{f}^{F 2 , n + 1} ( x , y ) ;$$

S10: repeating the steps S03 to S09 to acquire the fluid volume fraction Fⁿ(x, y) and the intermediate velocity

$${u}_{f}^{F 2 , n + 1} ( x , y )$$

in each grid cell in the computational domain;
S11: determining a particle velocity:
determining, by IBM and DEM methods, respectively, a fluid force

$${F}_{s 1}^{n}$$

and a collision force

$${F}_{s 2}^{n}$$

experienced by the solid particle;
determining the particle velocity: solving, based on a total fluid force and a total collision force experienced by a p-th particle, a translational velocity

$${v}_{s p}^{n + 1} ,$$

a rotational velocity

$${ω}_{s p}^{n + 1} ,$$

and a velocity vector

$${u}_{s p}^{n + 1}$$

of the p-th particle according to Newton's momentum equation and angular momentum equation as follows:

$${m}_{s p} \frac{{v}_{s p}^{n + 1} - {v}_{s p}^{n}}{Δ t j} = {( {F}_{s 1}^{n} )}_{p} + {( {F}_{s 2}^{n} )}_{p} \to {v}_{s p}^{n + 1} = {v}_{s p}^{n} + ( {( {F}_{s 1}^{n} )}_{p} + {( {F}_{s 2}^{n} )}_{p} ) \frac{Δ t}{{m}_{s p}}$$

$${I}_{s p} \frac{{ω}_{s p}^{n + 1} - {ω}_{s p}^{n}}{Δ t} = {R}_{s p}^{n} \times ( {( {F}_{s 1}^{n} )}_{p} + {( {F}_{s 2}^{n} )}_{p} ) \to {ω}_{s p}^{n + 1} = {ω}_{s p}^{n} + {R}_{s p}^{n} \times ( {( {F}_{s 1}^{n} )}_{p} + {( {F}_{s 2}^{n} )}_{p} ) \frac{Δ t}{{I}_{s p}}$$

$${u}_{s p}^{n + 1} = {v}_{s p}^{n + 1} + \frac{D}{2} {ω}_{s p}^{n + 1}$$

where, mₛₚ denotes a mass of the p-th particle; lₛₚ denotes an inertia tensor of the p-th particle;

$${R}_{s}^{n}$$

denotes a radius vector from a center of the p-th particle to a boundary of the p-th particle;

$${( {F}_{s 1}^{n} )}_{p}$$

denotes the total fluid force experienced by the p-th particle; and

$${( {F}_{s 2}^{n} )}_{p}$$

denotes the total collision force experienced by the p-th particle at the n-th time; and
acquiring the particle velocities of all particles, and acquiring the velocity vectors of all the particles in the computational domain, where the fluid force experienced by each grid cell occupied by the particle is denoted as

$${f}_{i b m}^{n} ( x , y ) ;$$

S12: determining a displacement dⁿ⁺¹ of the p-th solid particle at the (n+1)-th time and a solid volume fraction

$${∅}_{s}^{n + 1} ( x , y )$$

in the grid cell (Nₓ, N_{y}) at the (n+1)-th time;
S13: determining a final velocity uⁿ⁺¹(x, y) of the computational domain at the (n+1)-th time;
S14: solving a temperature and an interface heat flux density, specifically including:
A: calculating a heat flux density at a particle interface:
A-1: acquiring all solid interface grids based on the solid volume fraction

$${∅}_{s}^{n + 1} ( x , y )$$

at the (n+1)-th time, and incorporating all the solid interface grids into a set

$${H}_{g}^{n + 1} ,$$

where

$${H}_{g}^{n + 1} = ( {H}_{1} , {H}_{2} , … … {H}_{g} … … {H}_{G} ) ,$$

H_{g} denotes a g-th interface grid cell in the set

$${H}_{g}^{n + 1} ,$$

and G denotes a total number of interface grid cells in the set

$${H}_{g}^{n + 1} ;$$

A-2: dividing a temperature gradient in the interface grid cell H_{g} in a normal direction ((\hat{n}ⁿ⁺¹(H_{g})\hat{n}ⁿ⁺¹(H_{g}))·∇Tⁿ(H_{g})|ᵢⱼ) and a tangential direction (I−\hat{n}ⁿ⁺¹(H_{g})\hat{n}ⁿ⁺¹(H_{g})·∇Tⁿ(H_{g})|ᵢⱼ), where i and j respectively denote numbers of grids in the horizontal and vertical directions; Tⁿ(H_{g}) denotes a temperature in the interface grid cell H_{g} at the n-th time; \hat{n}ⁿ⁺¹(H_{g}) denotes a unit vector in the normal direction of the particle interface; and I denotes a unit matrix;
A-3: calculating thermal conductivity coefficients in the normal and tangential directions as follows:

$$\frac{1}{{λ}_{h 1}^{n + 1} ( {H}_{g} )} = \frac{1 - {∅}_{s}^{n + 1} ( {H}_{g} )}{{λ}_{f 1}} + \frac{{∅}_{s}^{n + 1} ( {H}_{g} )}{{λ}_{s}}$$

$${λ}_{a 1}^{n + 1} ( {H}_{g} ) = ( 1 - {∅}_{s}^{n + 1} ( {H}_{g} ) ) {λ}_{f} + {∅}_{s}^{n + 1} ( {H}_{g} ) {λ}_{s}$$

where,

$${λ}_{h 1}^{n + 1} ( {H}_{g} )$$

denotes a thermal conductivity of the interface grid cell H_{g} in the normal direction at the (n+1)-th time;

$${λ}_{a 1}^{n + 1} ( {H}_{g} )$$

denotes a thermal conductivity in the tangential direction at the (n+1)-th time; λₛ denotes a solid thermal conductivity coefficient; λ_{f} denotes a fluid thermal conductivity coefficient; if the solid interface Fⁿ⁺¹(H_{g})>0, λ_{f} is λ_{f1}; and if not, λ_{f} is λ_{f2};
A-4: calculating a heat flux

$${q}_{surf}^{n + 1} ( {H}_{g} )$$

at the interface grid as follows:

$${q}_{surf}^{n + 1} ( {H}_{g} ) = - {λ}_{h}^{n + 1} ( {H}_{g} ) ( ( {\hat{n}}^{n + 1} ( {H}_{g} ) {\hat{n}}^{n + 1} ( {H}_{g} ) ) \cdot ∇ {T}^{n} ( {H}_{g} ) {\vert}_{i j} ) - {λ}_{a}^{n + 1} ( {H}_{g} ) ( ( I - {\hat{n}}^{n + 1} ( {H}_{g} ) {\hat{n}}^{n + 1} ( {H}_{g} ) ) \cdot ∇ {T}^{n} ( {H}_{g} ) {\vert}_{i j} )$$

B: calculating a heat flux density at a fluid interface:
B-1: determining all liquid-liquid interface grids based on the fluid volume fraction Fⁿ⁺¹(x, y) at the (n+1)-th time; incorporating all the liquid-liquid interface grids into a set

$${F}_{h}^{n + 1} ,$$

where

$${F}_{h}^{n + 1} = ( {F}_{1} , {F}_{2} , … {F}_{h} … {F}_{H} ) ,$$

Fₕ denotes an h-th interface grid cell in the set

$${F}_{h}^{n + 1} ,$$

and H denotes a total number of interface grid cells in the set

$${F}_{h}^{n + 1} ;$$

B-2: dividing a temperature gradient in the interface grid cell Fₕ in a normal direction ((\hat{n}ⁿ⁺¹(Fₕ)\hat{n}ⁿ⁺¹(Fₕ))·∇Tⁿ(Fₕ)|ᵢⱼ) and a tangential direction ((I−\hat{n}ⁿ⁺¹(Fₕ)\hat{n}ⁿ⁺¹(Fₕ))·∇Tⁿ(Fₕ)|ᵢⱼ), where i and j respectively denote numbers of grids in the horizontal and vertical directions; Tⁿ(Fₕ) denotes a temperature in the interface grid cell Fₕ at the n-th time; \hat{n}ⁿ⁺¹(Fₕ) denotes a unit vector in the normal direction of the liquid-liquid interface; and I denotes a unit matrix;
B-3: calculating thermal conductivity coefficients in the normal and tangential directions as follows:

$$\frac{1}{{λ}_{h 2}^{n + 1} ( {F}_{h} )} = \frac{1 - {F}^{n + 1} ( {F}_{h} )}{{λ}_{f 2}} + \frac{{F}^{n + 1} ( {F}_{h} )}{{λ}_{f 1}}$$

$${λ}_{a 2}^{n + 1} ( {F}_{h} ) = ( 1 - {F}^{n + 1} ( {F}_{h} ) ) {λ}_{f 2} + {F}^{n + 1} ( {F}_{h} ) {λ}_{f 1}$$

where,

$${λ}_{h 2}^{n + 1} ( {F}_{h} )$$

denotes a thermal conductivity of the interface grid cell Fₕ in the normal direction at the (n+1)-th time;

$${λ}_{a 2}^{n + 1} ( {F}_{h} )$$

denotes a thermal conductivity in the tangential direction at the (n+1)-th time; and λ_{f1} and λ_{f2} denote the thermal conductivity coefficients of the first fluid and the second fluid, respectively; and
B-4: calculating a heat flux

$${q}_{surf}^{n + 1} ( {F}_{h} )$$

at the interface grid as follows:

$${q}_{surf}^{n + 1} ( {F}_{h} ) = - {λ}_{h}^{n + 1} ( {F}_{h} ) ( ( {\hat{n}}^{n + 1} ( {F}_{h} ) {\hat{n}}^{n + 1} ( {F}_{h} ) ) \cdot ∇ {T}^{n} ( {F}_{h} ) {\vert}_{ij} ) - {λ}_{a}^{n + 1} ( {F}_{h} ) ( ( I - {\hat{n}}^{n + 1} ( {F}_{h} ) {\hat{n}}^{n + 1} ( {F}_{h} ) ) \cdot ∇ {T}^{n} ( {F}_{h} ) {\vert}_{ij} )$$

C: performing, by a Crack-Nicolson method, temporal update on a diffusion term of an energy equation, and solving a temperature field in an Euler system; and
S15: determining whether to terminate a calculation: repeating the steps S03 to S14 if a current number of time steps n<Nₜ; and terminating the calculation if the current number of time steps n≥Nₜ.

Further, the reconstructing the interface shape for each grid cell at the n-th time through the PLIC method specifically includes:
determining, based on the fluid volume fraction Fⁿ(x, y) in the grid cell (Nₓ, N_{y}) at the n-th time, an interface unit normal vector

$$\hat{n} ( x , y ) = \frac{∇ {F}^{n} ( x , y )}{\vert ∇ {F}^{n} ( x , y ) \vert}$$

of the grid cell at the n-th time, where ∇ denotes a Hamiltonian operator,

$$∇ = \frac{\partial }{\partial x} i + \frac{\partial }{\partial y} j ;$$

i denotes a horizontal component; j denotes a vertical component; and η denotes a number of time steps, n∈[1, Nₜ]; and
determining, based on the interface unit normal vector \hat{n}(x, y) of the grid cell (Nₓ, N_{y}) at the n-th time and the fluid volume fraction Fⁿ(x, y) in the grid cell (Nₓ, N_{y}) at the n-th time, the interface shape for the grid cell (Nₓ, N_{y}) at the n-th time.

Further, the determining the boundary grid and solving the signed distance function Øⁿ(x, y) specifically includes:
determining, if the fluid volume fraction Fⁿ(x, y) in the grid cell at the n-th time is 0.5, that the grid cell is the boundary grid; and determining all boundary grids of the computational domain;
calculating a minimum distance from the grid cell (Nₓ, N_{y}) to each boundary grid, and acquiring a minimum distance d from the grid cell (Nₓ, N_{y}) to all the boundary grids, specifically, a minimum distance d from the grid cell (Nₓ, N_{y}) to a two-phase interface; and
determining, based on the fluid volume fraction Fⁿ(x, y) in the grid cell (Nₓ, N_{y}) at the n-th time, the signed distance function Øⁿ(x, y) of the grid cell (Nₓ, N_{y}) at the n-th time:

$${∅}^{n} ( x , y ) = \{ \begin{matrix}- d & if {F}^{n} ( x , y ) > 0.5 \\ 0 & if {F}^{n} ( x , y ) = 0.5 \\ d & if {F}^{n} ( x , y ) < 0.5\end{matrix} .$$

Further, the determining the interface curvature k(x, y) of the interface grid cell (Nₓ, N_{y}) specifically includes:
as for the liquid-liquid interface: calculating, based on the signed distance function Øⁿ(x, y) of the grid cell (Nₓ, N_{y}) at the n-th time, the interface curvature k(x, y) as follows:

$$k ( x , y ) = ∇ \cdot \frac{∇ {∅}^{n} ( x , y )}{\vert ∇ {∅}^{n} ( x , y ) \vert} ;$$

determining, if the fluid volume fraction in the grid cell (Nₓ, N_{y}) satisfies Fⁿ(x, y)∈(0,1) and the solid volume fraction satisfies

$${∅}_{s}^{n} ( x , y ) ∈ ( 0 , 1 ) ,$$

that the grid cell (Nₓ, N_{y}) is a three-phase contact cell; and correcting, in case of a three-phase contact, an interface unit normal vector of the grid cell on a contact line based on a contact angle boundary condition according to the following correction equation:

$$( x , y ) = {\hat{n}}_{s} ( x , y ) cos θ + {\hat{t}}_{s} ( x , y ) sin θ$$

$${\hat{t}}_{s} ( x , y ) = \frac{∇ F ( x , y ) - ( {\hat{n}}_{s} ( x , y ) \cdot ∇ F ( x , y ) ) {\hat{n}}_{s} ( x , y )}{\vert ∇ F ( x , y ) - ( {\hat{n}}_{s} ( x , y ) \cdot ∇ F ( x , y ) ) {\hat{n}}_{s} ( x , y ) \vert}$$

where, θ denotes a contact angle; \hat{n}ₛ(x, y) denotes a solid wall normal vector of the grid cell (Nₓ, N_{y}); and \hat{t}ₛ(x, y) denotes a solid wall tangent vector of the grid cell (Nₓ, N_{y}); and
determining the interface curvature k(x, y) of the grid cell (Nₓ, N_{y}): k(x, y)=∇· [symbol] (x, y).

Further, the determining the intermediate fluid velocity

$${u}_{f}^{F 2 , n + 1} ( x , y )$$

specifically includes:
solving a Navier-Stokes equation based on the velocity, a pressure, and the surface tension in the grid cell (Nₓ, N_{y}) at the n-th time to acquire the intermediate velocity

$${u}_{f}^{F 1 , n + 1} ( x , y )$$

in the grid cell (Nₓ, N_{y}) at the (n+1)-th time, specifically:

$${u}_{f}^{F 1 , n + 1} ( x , y ) = {u}_{f}^{n} ( x , y ) + Δ t ( {A}^{n} ( x , y ) + {B}^{n} ( x , y ) + {F}_{s}^{n} ( x , y ) ) / ρ ( {∅}^{n} ( x , y ) )$$

where, Δt denotes the time step; Aⁿ(x, y)=uⁿ(x, y)∇·uⁿ(x, y) denotes a convective term; and Bⁿ(x, y)=μ(Øⁿ(x, y))∇²uⁿ(x, y) denotes a viscosity term;
solving, by a fast Fourier transform method, a pressure Poisson equation, to acquire a pressure correction value pⁿ⁺¹(x, y) of the grid cell (Nₓ, N_{y}) at the (n+1)-th time;

$${∇}^{2} {P}^{n + 1} ( x , y ) = \frac{1}{Δ t} ∇ \cdot {u}_{f}^{F 1 , n + 1} ( x , y ) ;$$

and
correcting, based on the pressure correction value pⁿ⁺¹(x, y) of the grid cell (Nₓ, N_{y}) at the (n+1)-th time, the intermediate velocity

$${u}_{f}^{F 1 , n + 1} ( x , y )$$

in the grid cell (Nₓ, N_{y}) at the (n+1)-th time to acquire a corrected intermediate velocity

$${u}_{f}^{F 2 , n + 1} ( x , y ) ,$$

specifically:

$${u}_{f}^{F 2 , n + 1} ( x , y ) = {u}_{f}^{F 1 , n + 1} ( x , y ) - Δ t ∇ {P}^{n + 1} ( x , y ) .$$

Further, the determining, by the IBM and DEM methods, respectively, the fluid force

$${F}_{s 1}^{n}$$

and the collision force

$${F}_{s 2}^{n}$$

experienced by the solid particle specifically includes:
determining, by the IBM method, the fluid force

$${F}_{s 1}^{n}$$

experienced by the solid particle:
determining the fluid force experienced by the p-th particle at the n-th time through vector summation on fluid forces experienced by grids occupied by the p-th particle; determining a set

$${Q}_{p}^{n}$$

of all grid cells occupied by the p-th particle based on a center position and a radius of the p-th particle at the n-th time, where

$${Q}_{p}^{n} = ( {P}_{1} , {P}_{2} … {P}_{e} … {P}_{E} ) ,$$

Pₑ denotes an e-th grid cell in the set

$${Q}_{p}^{n} ;$$

and E denotes a total number of grid cells in the set

$${Q}_{p}^{n} ;$$

solving, by the IBM method, a fluid force

$${f}_{i b m i}^{n} ( {P}_{e} )$$

experienced by the grid cell Pₑ in the set Qₚ, where the method also allows a solid-liquid interface to satisfy a non-slip boundary condition, specifically:

$${f}_{i b m i}^{n} ( {P}_{e} ) = \frac{{ϕ}_{s}^{n} ( {P}_{e} ) ( {u}_{s}^{n} ( {P}_{e} ) - {u}_{f}^{F 2 , n + 1} ( {P}_{e} ) )}{Δ t}$$

where:

$${u}_{f}^{F 2 , n + 1} ( {P}_{e} )$$

denotes an intermediate velocity in the grid cell Pₑ at the (n+1)-th time;

$${u}_{s}^{n} ( {P}_{e} )$$

denotes a solid velocity in the grid cell Pₑ at the n-th time; and

$${∅}_{s}^{n} ( {P}_{e} )$$

denotes a volume fraction of the solid particle in the grid cell Pₑ at the n-th time;
acquiring the fluid force experienced by each grid cell in the set

$${Q}_{p}^{n}$$

at the n-th time, specifically, the fluid force experienced by each grid cell occupied by the p-th particle at the n-th time; and acquiring, by summation, the total fluid force

$${( {F}_{s 1}^{n} )}_{p}$$

experienced by the p-th particle:

$${( {F}_{s 1}^{n} )}_{p} = {\sum }_{e = 1}^{E} {f}_{i b m i}^{n} ( {P}_{e} )$$

where,

$${( {F}_{s 1}^{n} )}_{p}$$

denotes the toatl fluid force experienced by the p-th particle; and
determining, by the DEM method, the collision force

$${F}_{s 2}^{n}$$

experienced by the solid particle:
determining a set

$${Q}_{q}^{n}$$

of particles other than the p-th particle, where

$${Q}_{q}^{n} = ( {Q}_{1} , {Q}_{2} ... {Q}_{q} ... {Q}_{N - 1} ) ,$$

Q_{q} denotes a q-th particle in the set

$${Q}_{q}^{n} ,$$

and N denotes a number of particles in the computational domain;
determining a set

$${Q}_{w}^{n}$$

of walls, where w denotes different walls, and w=1, 2, 3, 4;
solving, by a DEM soft ball collision model, a collision force

$${( {f}_{c}^{n} )}_{p q}$$

between the p-th particle and the q-th particle at the n-th time and a collision force

$${( {f}_{c}^{n} )}_{p w}$$

between the p-th particle and a wall w at the n-th time:
if a center distance between the p-th particle and the q-th particle is greater than D: determining that the p-th particle does not collide with the q-th particle, specifically, the collision force

$${( {f}_{c}^{n} )}_{p q}$$

between the p-th particle and the q-th particle at the n-th time is 0;
if a distance between a center of the p-th particle and the wall w is greater than D/2: determining that the p-th particle does not collide with the wall w, specifically, the collision force

$${( {f}_{c}^{n} )}_{p w}$$

between the p-th particle and the wall w at the n-th time is 0;
if the center distance between the p-th particle and the q-th particle is less than D: determining that the p-th particle collides with the q-th particle, and calculating the collision force

$${( {f}_{c}^{n} )}_{p q}$$

between the p-th particle and the q-th particle as follows:

$${( {f}_{c n}^{n} )}_{p q} = - k {d}_{n}^{n} - η {v}_{n}^{n}$$

$${v}_{n}^{n} = ( {v}_{r q}^{n} \cdot \vec{n} ) \vec{n}$$

$${( {f}_{c t}^{n} )}_{pq} = - ε {d}_{t}^{n} - η {v}_{t}^{n}$$

$${v}_{t}^{n} = {v}_{r q}^{n} - {v}_{n}^{n}$$

$${( {f}_{c}^{n} )}_{p q} = {( {f}_{c n}^{n} )}_{p q} + {( {f}_{ct}^{n} )}_{p q}$$

where, ε denotes an elastic coefficient; η denotes a viscous dissipation coefficient;

$${d}_{t}^{n} and {d}_{n}^{n}$$

denote displacements in the tangential and normal directions, respectively;

$${v}_{r q}^{n}$$

denotes a relative velocity between the p-th and q-th particles;

$${v}_{t}^{n} and {v}_{n}^{n}$$

denote velocities or ine p-th particle in the tangential and normal directions, respectively; and \vec{n} denotes a unit normal vector pointing from the center of the p-th particle to a center of the q-th particle;
if the distance between the center of the p-th particle and the wall w is less than D/2: determining that the p-th particle collides with the wall w, and calculating the collision force

$${( {f}_{c}^{n} )}_{p w}$$

between the p-th particle and the wall w as follows:

$${( {f}_{c n}^{n} )}_{p w} = - k {d}_{n}^{n} - η {v}_{n}^{n}$$

$${v}_{n}^{n} = ( {v}_{r w}^{n} \cdot \vec{n} ) \vec{n}$$

$${( {f}_{ct}^{n} )}_{p w} = - ε {d}_{t}^{n} - η {v}_{t}^{n}$$

$${v}_{t}^{n} = {v}_{r w}^{n} - {v}_{n}^{n}$$

$${( {f}_{c}^{n} )}_{p w} = {( {f}_{c n}^{n} )}_{p w} + {( {f}_{c t}^{n} )}_{p w}$$

where,

$${v}_{r w}^{n}$$

denotes a relative velocity between the p-th particle and the wall w; and \vec{n} denotes a unit normal vector pointing vertically from the center of the p-th particle to the wall w;
the total collision force

$${( {F}_{s 2}^{n} )}_{p}$$

experienced by the p-th particle at the n-th time is a sum of collision forces between the p-th particle and other particles or walls:

$${( {F}_{s 2}^{n} )}_{p} = {\sum }_{q = 1}^{N - 1} {( {f}_{c}^{n} )}_{p q} + {( {f}_{c}^{n} )}_{p w} .$$

Further, the determining the displacement dⁿ⁺¹ of the p-th solid particle at the (n+1)-th time specifically includes:
decomposing the velocity vector

$${u}_{s p}^{n + 1}$$

of the p-th particle into a horizontal component velocity

$${u}_{s p x}^{n + 1}$$

and a vertical component velocity

$${u}_{spy}^{n + 1} ;$$

and calculating, based on the horizontal component velocity

$${u}_{spx}^{n + 1}$$

and the vertical component velocity

$${u}_{spy}^{n + 1}$$

of the p-th particle, horizontal and vertical displacements of the p-th particle at a subsequent time step Δt, and acquiring a position of the p-th particle at the (n+1)-th time:

$${x}_{sp}^{n + 1} = {x}_{sp}^{n} + \frac{Δ t}{2} ( {u}_{spx}^{n + 1} + {u}_{spx}^{n} )$$

$${y}_{sp}^{n + 1} = {y}_{sp}^{n} + \frac{Δ t}{2} ( {u}_{spy}^{n + 1} + {u}_{spy}^{n} )$$

$${d}_{p}^{n + 1} = ( {x}_{sp}^{n + 1} , {y}_{sp}^{n + 1} ) - ( {x}_{sp}^{n} , {y}_{sp}^{n} )$$

where,

$${x}_{sp}^{n} and {y}_{sp}^{n}$$

denote horizontal and vertical coordinates of the p-th particle at the n-th time, respectively;

$${u}_{spx}^{n} and {u}_{spy}^{n}$$

denote horizontal and vertical component velocities of the p-th particle at the n-th time, respectively; and

$${d}_{p}^{n + 1}$$

denotes a displacement of the p-th particle from the n-th time to the (n+1)-th time.

Further, the determining the solid volume fraction

$${∅}_{s}^{n + 1} ( x , y )$$

in the grid cell (Nₓ, N_{y}) at the (n+1)-th time specifically includes:
if a minimum distance between the grid cell (Nₓ, N_{y}) and the center

$$( {x}_{sp}^{n + 1} , {y}_{sp}^{n + 1} )$$

of the p-th particle is less than D/2: determining the volume fraction of the solid particle in the grid cell (Nₓ, N_{y}) at the n-th time as

$${∅}_{sn}^{n + 1} ( x , y ) = 1 ;$$

if a maximum distance between the grid cell (Nₓ, N_{y}) and the center

$$( {x}_{sp}^{n + 1} , {y}_{sp}^{n + 1} )$$

of the p-th particle is greater than D/2: determining the volume fraction of the solid particle in the grid cell (Nₓ, N_{y}) at the n-th time as

$${∅}_{sn}^{n + 1} ( x , y ) = 0 ;$$

if the minimum distance between the grid cell (Nₓ, N_{y}) and the center

$$( {x}_{sp}^{n + 1} , {y}_{sp}^{n + 1} )$$

of the p-th particle is greater than D/2 and the maximum distance is less than D/2: determining that the grid cell (Nₓ, N_{y}) at the n-th time is at a solid-liquid boundary, and calculating the volume fraction of the grid cell as follows:

$${∅}_{sn}^{n + 1} ( x , y ) = \frac{1}{2} ( 1 - tan h ( \frac{h}{γ β Δ x} ) )$$

$$β = \vert {\hat{n}}_{spx}^{n + 1} ( x , y ) \vert + \vert {\hat{n}}_{spy}^{n + 1} ( x , y ) \vert$$

$$γ = 0.05 ( 1 - {β}^{2} ) + 0.3$$

where, h denotes a distance from the solid-liquid interface to a center of the grid cell (Nₓ, N_{y}); Δx denotes a grid size;

$${\hat{n}}_{spx}^{n + 1} ( x , y )$$

denotes a horizontal component of a normal vector

$${\hat{n}}_{sp}^{n + 1} ( x , y )$$

of the solid-liquid interface,

$${\hat{n}}_{spx}^{n + 1} ( x , y ) = 2 ( x - {x}_{sp}^{n + 1} ) / D ; and {\hat{n}}_{spy}^{n + 1} ( x , y )$$

denotes a vertical component of the normal vector

$${\hat{n}}_{sp}^{n + 1} ( x , y )$$

of the solid-liquid interface,

$${\hat{n}}_{spy}^{n + 1} ( x , y ) = 2 ( y - {y}_{sp}^{n + 1} ) / D ;$$

determining, based on the displacement and solid volume fraction

$${∅}_{sp}^{n + 1} ( x , y )$$

of each particle, the solid volume fraction

$${∅}_{s}^{n + 1} ( x , y )$$

in the grid cell (Nₓ, N_{y}) of the computational domain at the (n+1)-th time:

$${ϕ}_{s}^{n + 1} ( x , y ) = {\sum }_{p = 1}^{N} {ϕ}_{sp}^{n + 1} ( x , y )$$

$$if$$

$${∅}_{s}^{n + 1} ( x , y ) > 1 , {∅}_{s}^{n + 1} ( x , y ) = 1 .$$

Further, the determining the final velocity uⁿ⁺¹(x, y) of the computational domain at the (n+1)-th time specifically includes:
defining a force exerted by the particle on the fluid in the grid cell (Nₓ, N_{y}) at the n-th time as

$$- {f}_{ibm}^{n} ( x , y ) ;$$

and acquiring, based on

$$- {f}_{ibm}^{n} ( x , y ) ,$$

the fluid velocity at the (n+1)-th time:

$${u}_{f}^{n + 1} ( x , y ) = {u}_{f}^{F 2} ( x , y ) + {f}_{ibm}^{n} ( x , y ) \cdot Δ t ;$$

determining the final velocity uⁿ⁺¹(x, y) of the computational domain as a whole at the (n+1)-th time as follows:

$${u}^{n + 1} ( x , y ) = ( 1 - {∅}_{s}^{n + 1} ( x , y ) ) {u}_{f}^{n + 1} ( x , y ) + {∅}_{s}^{n + 1} ( x , y ) {u}_{s}^{n + 1} ( x , y ) .$$

A three-phase flow and heat transfer coupled simulation system based on IBM-VOSET-DEM includes a storage medium, where the storage medium is configured to store a program compiled with the three-phase flow and heat transfer coupled simulation method based on the IBM-VOSET-DEM.

The present disclosure has the following advantages:

In the present disclosure, the three-phase flow and heat transfer coupled simulation method and system based on IBM-VOSET-DEM can capture the three-phase interface, simultaneously acquire momentum exchanges of the fluid-fluid interface, the fluid-solid interface, and the solid-solid interface, and acquire the nearby heat flux density of the interfaces, thereby more accurately deriving the internal flow and heat transfer phenomena of the three-phase system.

In the present disclosure, the three-phase flow and heat transfer coupled simulation method and system based on IBM-VOSET-DEM capture a liquid-liquid interface through the VOSET method, overcoming the disadvantage of the LS method that is likely to cause non-conservation of fluid mass in calculation and the disadvantage of the VOF method that has large calculation error of interface curvature and poor effect of abrupt physical quantities close to the smooth interface.

In the present disclosure, the three-phase flow and heat transfer coupled simulation method and system based on IBM-VOSET-DEM use the IBM method to mark the fluid-solid interface with a series of Lagrangian points, avoiding body-fitted grid generation at particle boundaries in traditional methods and reducing computational costs. Meanwhile, by adding a force source term to the momentum equation, the present disclosure can solve the momentum exchange between fluid and solid, and can also satisfy the non-slip boundary condition at the fluid-solid interface.

In the present disclosure, the three-phase flow and heat transfer coupled simulation method and system based on IBM-VOSET-DEM can accurately acquire and track the motion information of solid particles by calculating the solid collision force by the DEM soft ball model.

In the present disclosure, the three-phase flow and heat transfer coupled simulation method and system based on IBM-VOSET-DEM adopt an interface heat flux density model. This model considers the conjugate heat transfer effects at the solid-liquid and liquid-liquid interfaces, takes into account the interface direction, and solves the temperature field in the Euler system. This model is compatible with the immersed solid method, and this calculation method is more in line with actual heat transfer, which can more accurately simulate boundary heat transfer.

### BRIEF DESCRIPTION OF THE DRAWINGS

To describe the technical solutions in the embodiments of the present disclosure or in the prior art clearly, the drawings required for describing the embodiments or the prior art will be briefly described below. Apparently, the drawings in the following description show some embodiments of the present disclosure, and a person of ordinary skill in the art may still derive other drawings from these drawings without creative efforts.

FIG. 1 is a flowchart of a three-phase flow and heat transfer coupled simulation method based on IBM-VOSET-DEM according to the present disclosure;

FIG. 2 is a calculation flowchart of the VOSET method according to the present disclosure;

FIG. 3 is a schematic diagram of a computational domain according to an embodiment of the present disclosure;

FIG. 4 is a schematic diagram of a geometric calculation method for calculating a signed distance function according to the present disclosure;

FIG. 5 is a schematic diagram of a contact angle boundary condition according to the present disclosure;

FIG. 6 is a calculation flowchart of fluid motion according to the present disclosure;

FIG. 7 is a calculation flowchart of solid motion according to the present disclosure;

FIG. 8 is a schematic diagram of calculating heat conductivities of a grid on a solid-liquid interface in normal and tangential directions according to the present disclosure;

FIG. 9 is a diagram showing a simulation result that a liquid droplet collides with a spherical solid particle according to an embodiment of the present disclosure;

FIG. 10 shows a comparison between an embodiment and an experiment of the present disclosure on a ratio of a minimum height of the liquid droplet to an initial radius of the liquid droplet after the liquid droplet collides with the spherical solid particle; and

FIG. 11 shows a comparison between an embodiment and an experiment of the present disclosure on a volume variation over time in an evaporation process of the liquid droplet on the hot spherical solid particle.

### DETAILED DESCRIPTION OF THE EMBODIMENTS

The embodiments of the present disclosure are described below in detail. Examples of the embodiments are shown in the drawings. The same or similar numerals represent the same or similar elements or elements having the same or similar functions throughout the specification. The embodiments described below with reference to the drawings are exemplary, and are intended to explain the present disclosure but should not be construed as a limitation to the present disclosure.

It should be understood that, in the description of the present disclosure, the terms such as “central”, “longitudinal”, “transverse”, “length”, “width”, “thickness”, “upper”, “lower”, “axial”, “radial”, “vertical”, “horizontal”, “inner”, and “outer” are intended to indicate orientations or positional relations shown in the drawings. It should be noted that these terms are merely intended to facilitate a simple description of the present disclosure, rather than to indicate or imply that the mentioned apparatus or elements must have the specific orientation or be constructed and operated in the specific orientation. Therefore, these terms may not be construed as a limitation to the present disclosure. In addition, the terms “first” and “second” are merely intended for a purpose of description, and shall not be understood as an indication or implication of relative importance or implicit indication of a quantity of indicated technical features. Thus, features defined with “first” and “second” may explicitly or implicitly include one or more of the features. In the description of the present disclosure, “a plurality of” means two or more, unless otherwise specifically defined.

In the present disclosure, unless otherwise clearly specified and limited, the terms “installed”, “connected with”, “connected to”, and “fixed” should be understood in a broard sense. For example, the connection may be a fixed connection, a detachable connection or an integrated connection, may be a mechanical connection or an electrical connection, may be a direct connection or an indirect connection with use of an intermediate medium, or may be intercommunication between two components. Those of ordinary skill in the art may understand specific meanings of the above terms in the present disclosure based on a specific situation.

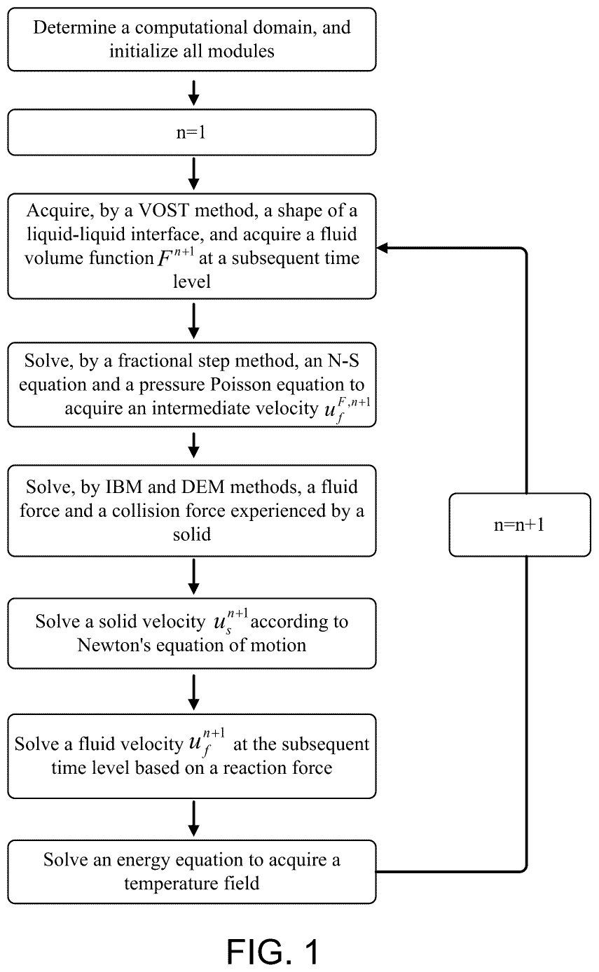

As shown in FIG. 1, the present disclosure provides a three-phase flow and heat transfer coupled simulation method based on IBM-VOSET-DEM, including the following steps.

S01. A computational domain is determined and divided into grids. A size of the computational domain is defined as length*height (L*H), and a number of particles and a particle size in the computational domain are respectively defined as N and D, respectively. The computational domain is divided into grids (N₁, N₂) in an Euler system. N₁ denotes a total number of grids in a horizontal direction; and N₂ denotes a total number of grids in a vertical direction. Any grid in the computational domain is denoted as (Nₓ, N_{y}), x∈[1, N₁], y∈[1, N₂]. A calculation time step is denoted as Δt, and a total number of time steps is denoted as Nₜ.

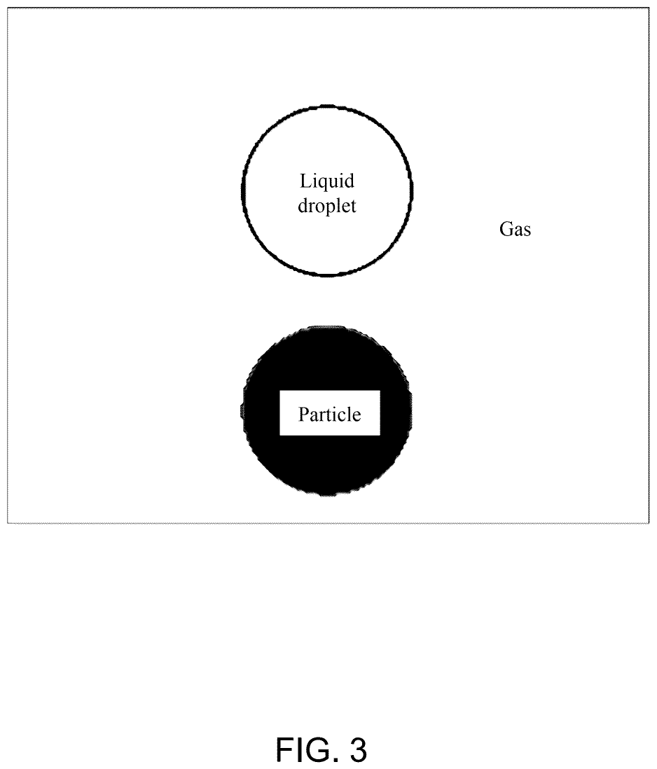

FIG. 3 shows the computational domain of Embodiment 1. The computational domain (L=1 mm, H=1 mm) includes a solid particle phase, a gas phase, and a liquid phase, where number of particles N=1, particle size D=300 μm, and liquid droplet diameter 300 μm. The computational domain is divided into grids (Nᵢ, Nⱼ) in an Euler system, where Nᵢ=128 and Nⱼ=128 denote the number of grids in horizontal and vertical directions, respectively. The calculation time step is Δt=1×10⁻⁵ s, and the total number of time steps is Nₜ=1×10⁶.

S02. Parameters are initialized. The following parameters are determined: fluid velocity

$${u}_{f}^{0} ( x , y )$$

in each grid cell at an initial time, fluid temperature

$${T}_{f}^{0} ( x , y )$$

in each grid cell at the initial time, and fluid volume fraction F⁰(x, y) in each grid cell at the initial time, center position (xₛ, yₛ) of each solid particle at the initial time, solid velocity

$${u}_{s}^{0} ( x , y )$$

in each grid cell at the initial time, solid temperature

$${T}_{s}^{0} ( x , y )$$

in each grid cell at the initial time, and solid volume fraction

$${∅}_{s}^{0} ( x , y )$$

in each grid cell at the initial time. All thermophysical parameters are determined, including: density ρ₁ of a first fluid, density ρ₂ of a second fluid, density ρₛ of the solid particle, viscosity μ₁ of the first fluid, viscosity μ₂ of the second fluid, thermal conductivity coefficient λ₁ of the first fluid, thermal conductivity coefficient λ₂ of the second fluid, and thermal conductivity coefficient λₛ of the solid particle.

In Embodiment 1, the parameters are initialized. The first fluid is a liquid droplet, and the second fluid is a gas. The center of the liquid droplet is (Nₓ=64, N_{y}=75). Δt this center, the fluid volume fraction is 1 in grid cells within a radius of 150 μm and 0 at other positions. Δt the initial time, in the grid cell where the liquid droplet and gas are located, the velocity is

$${u}_{f}^{0} = 0 ,$$

and the temperature is

$${T}_{f}^{0} = 25 ° C .$$

The center of the solid particle is (Nₓ=64, N_{y}=35). At this center, the solid volume fraction is 1 in grid cells within a radius of 100 μm and 0 at other positions. In solid grid cells, the velocity is

$${u}_{s}^{0} = 0 ,$$

and the temperature is

$${T}_{s}^{0} = 25 ° C .$$

The density of the liquid droplet is ρ₁=1000 kg/m³, the density of the gas is ρ₂=1 kg/m³, the density of the solid particle is ρₛ=1000 kg/m³, the viscosity of the liquid droplet is μ₁=3×10⁻³ Pa·s, the viscosity of the second fluid is μ₂=2×10⁻⁶ Pa·s, the thermal conductivity coefficient of the liquid droplet is λ₁=0.59W/m·k, the thermal conductivity coefficient of the second fluid is λ₂=0.02W/m·k, and the thermal conductivity coefficient of the solid particles is λₛ=59W/m·k.

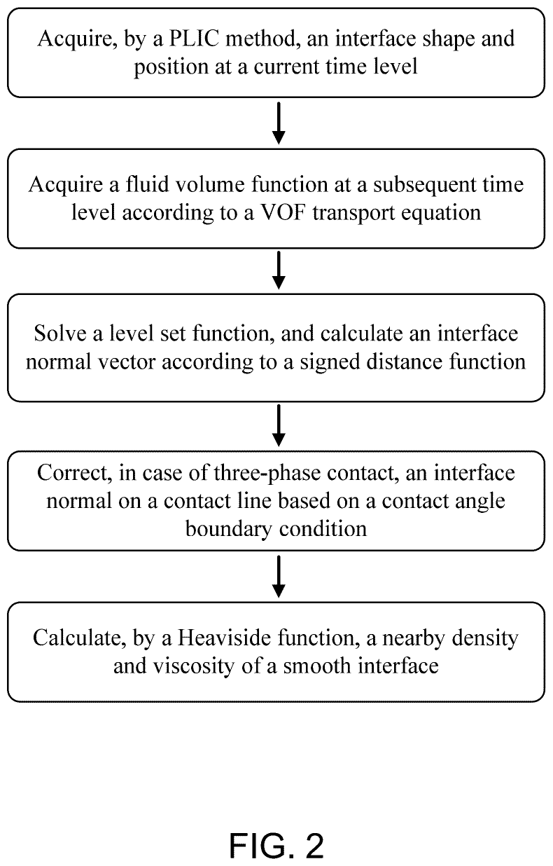

S03. A liquid-liquid interface is reconstructed, as shown in FIG. 2.

If fluid volume fraction Fⁿ(x, y)∈(0,1), it is determined that the grid cell (Nₓ, N_{y}) at an n-th time is a liquid-liquid interface grid. If Fⁿ(x, y)=0, it is determined that the grid cell (Nₓ, N_{y}) at the n-th time is filled with the second fluid. If Fⁿ(x, y)=1, it is determined that the grid cell (Nₓ, N_{y}) at the n-th time is filled with the first fluid.

If the grid (x, y) is a liquid-liquid interface grid, it is necessary to reconstruct the interface shape at this time. In this case, the interface shape for each grid cell at the n-th time is reconstructed through a particle line-segment interface calculation (PLIC) method. Specifically:

Based on the fluid volume fraction Fⁿ(x, y) in the grid cell (Nₓ, N_{y}) at the n-th time, interface unit normal vector

$$\hat{n} ( x , γ ) = \frac{∇ {F}^{n} ( x , y )}{\vert ∇ {F}^{n} ( x , y ) \vert}$$

of the grid cell at the n-th time is determined, where ∇ denotes a Hamiltonian operator,

$$∇ = \frac{\partial }{\partial x} i + \frac{\partial }{\partial y} j ;$$

i denotes a horizontal component; j denotes a vertical component; and η denotes a number of time steps, n∈[1, Nₜ].

Based on the grid unit normal vector \hat{n}(x, y) of the grid cell (Nₓ, N_{y}) at the n-th time and the fluid volume fraction Fⁿ(x, y) in the grid cell (Nₓ, N_{y}) at the n-th time, the interface shape for the grid cell (Nₓ, N_{y}) at the n-th time is determined.

S04. A fluid volume fraction at an (n+1)-th time is solved.

Based on a velocity in the grid cell (Nₓ, N_{y}) at the n-th time and fluid volume fraction Fⁿ(x, y) in the grid cell (Nₓ, N_{y}) at the n-th time, a fluid volume flowing into and out of the grid cell (Nₓ, N_{y}) within a time of Δt is acquired, thereby acquiring fluid volume fraction Fⁿ⁺¹(x, y) in the grid cell at the (n+1)-th time. Specifically, the solving equation is a VOF transport equation,

$$\frac{\partial F}{\partial t} + ∇ \cdot ( uF ) = 0 .$$

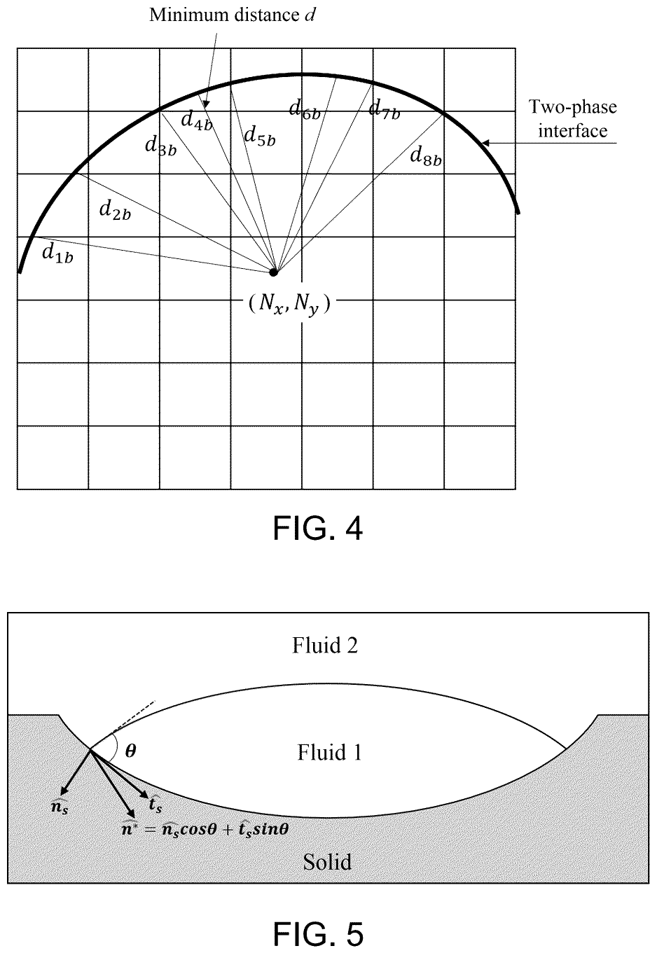

S05. If the grid (x, y) is a liquid-liquid interface grid, a signed distance function is solved. As shown in FIG. 4, this step is specifically as follows.

If the fluid volume fraction Fⁿ(x, y) in the grid cell at the n-th time is 0.5, it is determined that the grid cell is a boundary grid, and all boundary grids of the computational domain are determined.

A minimum distance from the grid cell (Nₓ, N_{y}) to each boundary grid is calculated, thereby acquiring minimum distance d from the grid cell (Nₓ, N_{y}) to all the boundary grids. Specifically, minimum distance d from the grid cell (Nₓ, N_{y}) to the two-phase interface is acquired. Specifically, as shown in FIG. 4, the minimum distances from the grid cell (Nₓ, N_{y}) to the boundary grids are denoted as d₁ₐ, d_{1b} . . . d_{8b}, respectively. Among d_{1b}, d_{1b} . . . d_{8b}, d_{4b} is the smallest. Therefore, the minimum distance from the grid cell (Nₓ, N_{y}) to each boundary grid is determined as d_{4b}.

Based on the fluid volume fraction Fⁿ(x, y) in the grid cell (Nₓ, N_{y}) at the n-th time, the signed distance function Øⁿ(x, y) of the grid cell (Nₓ, N_{y}) at the n-th time is determined:

$${∅}^{n} ( x , y ) = \{ \begin{matrix}- d & if {F}^{n} ( x , y ) > 0.5 \\ 0 & if {F}^{n} ( x , y ) = 0.5 \\ d & if {F}^{n} ( x , y ) < 0.5\end{matrix} .$$

S06. An interface curvature is solved.

There are three cases.

In a first case, as for a liquid-liquid interface: based on the signed distance function Øⁿ(x, y) of the grid cell (Nₓ, N_{y}) at the n-th time, the interface curvature k(x, y) is calculated as follows:

$$k ( x , y ) = ∇ \cdot \frac{∇ {∅}^{n} ( x , y )}{\vert ∇ {∅}^{n} ( x , y ) \vert} .$$

In a second case, if the fluid volume fraction in the grid cell (Nₓ, N_{y}) satisfies Fⁿ(x, y)∈(0,1) and the solid volume fraction satisfies

$${∅}_{s}^{n} ( x , y ) ∈ ( 0 , 1 ) ,$$

it is determined that the grid cell (Nₓ, N_{y}) is a three-phase contact cell. As shown in FIG. 5, in case of a three-phase contact, an interface unit normal vector of the grid cell on a contact line is corrected based on a contact angle boundary condition according to the following correction equation:

$$( x , y ) = {\hat{n}}_{s} ( x , y ) cos θ + {\hat{t}}_{s} ( x , y ) sin θ$$

$${\hat{t}}_{s} ( x , y ) = \frac{∇ F ( x , y ) - ( {\hat{n}}_{s} ( x , y ) \cdot ∇ F ( x , y ) ) {\hat{n}}_{s} ( x , y )}{\vert ∇ F ( x , y ) - ( {\hat{n}}_{s} ( x , y ) \cdot ∇ F ( x , y ) ) {\hat{n}}_{s} ( x , y ) \vert}$$

where, θ denotes a contact angle; \hat{n}ₛ(x, y) denotes a solid wall normal vector of the grid cell (Nₓ, N_{y}); and \hat{t}ₛ(x, y) denotes a solid wall tangent vector of the grid cell (Nₓ, N_{y}). In Embodiment 1, the contact angles θ are 30°, 60°, 90°, 120°, and 150°, respectively.

The interface curvature k(x, y) of the grid cell (Nₓ, N_{y}) is determined, k(x, y)=∇· [symbol] (x, y).

In a third case, if there is no interface, there is no surface tension, that is, k(x, y)=0.

S07. Abrupt physical quantities at a smooth interface are determined. A nearby density and viscosity of the smooth interface of the grid cell (Nₓ, N_{y}) at the n-th time are determined by a Heaviside function.

A smooth density in the grid cell (Nₓ, N_{y}) at the n-th time is calculated as follows:

$$ρ ( {∅}^{n} ( x , y ) ) = {ρ}_{1} ( 1 - H ( {∅}^{n} ( x , y ) ) ) + {ρ}_{2} H ( {∅}^{n} ( x , y ) )$$

A smooth viscosity in the grid cell (Nₓ, N_{y}) at the n-th time is calculated as follows:

$$μ ( {∅}^{n} ( x , y ) ) = {μ}_{1} ( 1 - H ( {∅}^{n} ( x , y ) ) ) + {μ}_{2} H ( {∅}^{n} ( x , y ) )$$

The Heaviside function H(Øⁿ) is expressed as follows:

$$H ( {∅}^{n} ( x , y ) ) = \{ \begin{matrix}0 & if {∅}^{n} ( x , y ) < - ϵ \\ \frac{1}{2} - [ 1 + \frac{{∅}^{n} ( x , y )}{ϵ} + \frac{1}{π} sin ( \frac{π {∅}^{n} ( x , y )}{ϵ} ) ] & if \vert {∅}^{n} ( x , y ) \vert \leq ϵ \\ 1 & if {∅}^{n} ( x , y ) > ϵ\end{matrix}$$

∈ denotes a thickness of the smooth interface, which is generally 1.5 or 2 times of the grid size.

S08. A surface tension of the interface is solved.

The surface tension at the liquid-liquid interface, as mentioned in the step S03, is solved. Specifically, the surface tension

$${F}_{s}^{n} ( x , y )$$

in the grid cell (Nₓ, N_{y}) at the n-th time is calculated by a continuous surface force model as follows:

$${F}_{s}^{n} ( x , y ) = - σ k ( x , y ) δ ( {∅}^{n} ( x , y ) ) ∇ {∅}^{n} ( x , y )$$

where, σ denotes a surface tension coefficient, and

$$δ ( {∅}^{n} ( x , y ) ) = \frac{d H ( {∅}^{n} ( x , y ) )}{d {∅}^{n} ( x , y )} .$$

If there is no interface, there is no surface tension, and the surface tension in the grid cell (Nₓ, N_{y}) at the n-th time is

$${F}_{s}^{n} ( x , y ) = 0 .$$

S09. Intermediate fluid velocity

$${u}_{f}^{F 2 , n + 1} ( x , y )$$

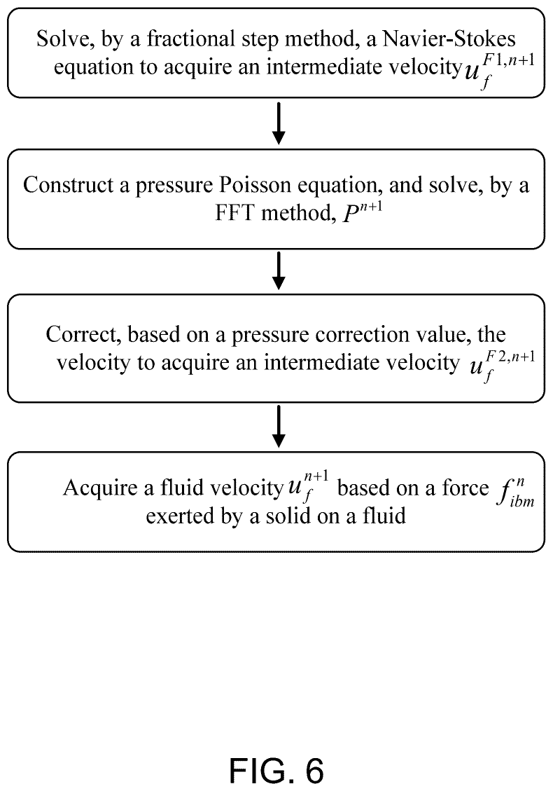

is solved, as shown in FIG. 6.

A Navier-Stokes equation is solved based on the velocity, a pressure, and the surface tension in the grid cell (Nₓ, N_{y}) at the n-th time, and the intermediate velocity

$${u}_{f}^{F 1 , n + 1} ( x , y )$$

in the grid cell (Nₓ, N_{y}) at the (n+1)-th time is acquired, specifically:

$${u}_{f}^{F 1 , n + 1} ( x , y ) = {u}_{f}^{n} ( x , y ) + Δ t ( {A}^{n} ( x , y ) + {B}^{n} ( x , y ) + {F}_{s}^{n} ( x , y ) ) / ρ ( {∅}^{n} ( x , y ) )$$

where, Δt denotes the time step; Aⁿ(x, y)=uⁿ(x, y)∇·uⁿ(x, y) denotes a convective term; and Bⁿ(x, y)=μ(Øⁿ(x, y))∇²uⁿ(x, y) denotes a viscosity term.

A pressure Poisson equation is solved by a fast Fourier transform method, and pressure correction value pⁿ⁺¹(x, y) of the grid cell (Nₓ, N_{y}) at the (n+1)-th time is acquired:

$${∇}^{2} {P}^{n + 1} ( x , y ) = \frac{1}{Δ t} ∇ \cdot {u}_{f}^{F 1 , n + 1} ( x , y ) .$$

Based on the pressure correction value pⁿ⁺¹(x, y) of the grid cell (Nₓ, N_{y}) at the (n+1)-th time, the intermediate velocity

$${u}_{f}^{F 1 , n + 1} ( x , y )$$

in the grid cell (Nₓ, N_{y}) at the (n+1)-th time is corrected to acquire a corrected intermediate velocity

$${u}_{f}^{F 2 , n + 1} ( x , y ) ,$$

specifically:

$${u}_{f}^{F 2 , n + 1} ( x , y ) = {u}_{f}^{F 1 , n + 1} ( x , y ) - Δ t ∇ {P}^{n + 1} ( x , y ) ;$$

S10. The steps S03 to S09 are repeated to acquire fluid volume fraction Fⁿ(x, y) and intermediate velocity

$${u}_{f}^{F 2 , n + 1} ( x , y )$$

in each grid cell in the computational domain.

S11. A particle velocity is solved.

Due to the fact that particles are rigid bodies, the velocity of each particle is consistent at all positions. By solving the resultant force experienced by each particle, the overall velocity of each particle can be determined, and the resultant force experienced by each particle includes the fluid force

$${F}_{s 1}^{n}$$

and the collision force

$${F}_{s 2}^{n} .$$

The fluid force

$${F}_{s 1}^{n}$$

and collision force

$${F}_{s 2}^{n}$$

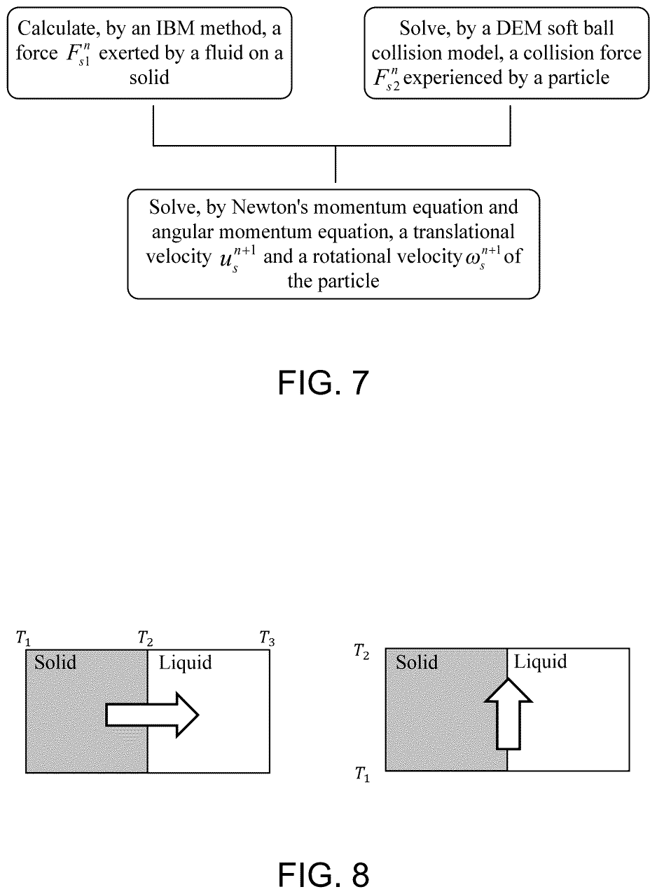

experienced by the solid particle are calculated by the IBM and DEM methods, respectively, as shown in FIG. 7.

A. The fluid force is calculated.

The fluid force experienced by the p-th particle at the n-th time is determined through vector summation on fluid forces experienced by grids occupied by the particle. Set

$${Q}_{p}^{n}$$

of all grid cells occupied by the p-th particle is determined based on a center position and a radius of the p-th particle at the n-th time, where

$${Q}_{p}^{n} = ( {P}_{1} , {P}_{2} … … {P}_{e} … … {P}_{E} ) ,$$

Pₑ denotes an e-th grid cell in the set

$${Q}_{p}^{n} ;$$

and E denotes a total number of grid cells in the set

$${Q}_{p}^{n} .$$

Fluid force

$${f}_{i b m i}^{n} ( {P}_{e} )$$

experienced by the grid cell Pₑ in the set Qₚ is solved by the IBM method, where the method also allows a solid-liquid interface to satisfy a non-slip boundary condition, specifically:

$${f}_{i b m i}^{n} ( {P}_{e} ) = \frac{{ϕ}_{s}^{n} ( {P}_{e} ) ( {u}_{s}^{n} ( {P}_{e} ) - {u}_{f}^{F 2 , n + 1} ( {P}_{e} ) )}{Δ t}$$

Where:

$${u}_{f}^{F 2 , n + 1} ( {P}_{e} )$$

denotes an intermediate velocity in the grid cell Pₑ at the (n+1)-th time;

$${u}_{s}^{n} ( {P}_{e} )$$

denotes a solid velocity in the grid cell Pₑ at the n-th time; and

$${∅}_{s}^{n} ( {P}_{e} )$$

denotes a volume fraction of the solid particle in the grid cell Pₑ at the n-th time.

According to the above equation, the fluid force experienced by each grid cell in the set

$${Q}_{p}^{n}$$

at the n-th time is solved. Specifically, the fluid force experienced by each grid cell occupied by the p-th particle at the n-th time is solved. The total fluid force

$${( {F}_{s 1}^{n} )}_{p}$$

experienced by the p-th particle is acquired through summation.

$${( {F}_{s 1}^{n} )}_{p} = {\sum }_{e = 1}^{E} {f}_{i b m i}^{n} ( {P}_{e} )$$

where

$$( {F}_{s 1}^{n} ) p$$

denotes the total fluid force experienced by the p-th particle.

B. The collision force is calculated.

Set

$${Q}_{q}^{n}$$

of particles other than the p-th particle is determined,

$${Q}_{q}^{n} = ( {Q}_{1} , {Q}_{2} … … {Q}_{q} … … {Q}_{N - 1} ) ,$$

where Q_{q} denotes a q-th particle in the set

$${Q}_{q}^{n} ;$$

and N denotes a number of particles in the computational domain.

Set

$${Q}_{w}^{n}$$

of walls is determined, where w denotes different walls, w=1, 2, 3, 4.

Collision force

$${( {f}_{c}^{n} )}_{p q}$$

between the p-th particle and the q-th particle at the n-th time and collision force

$${( {f}_{c}^{n} )}_{p w}$$

between the p-th particle and the wall w at the n-th time are solved by a DEM soft ball collision model.

If a center distance between the p-th particle and the q-th particle is greater than D, it is determined that the p-th particle does not collide with the q-th particle, specifically, the collision force

$${( {f}_{c}^{n} )}_{p q}$$

between the p-th particle and the q-th particle at the n-th time is 0.

If a distance between a center of the p-th particle and the wall w is greater than D/2, it is determined that the p-th particle does not collided with the wall w, specifically, the collision force

$${( {f}_{c}^{n} )}_{p w}$$

between the p-th particle and the wall w at the n-th time is 0.

If the center distance between the p-th particle and the q-th particle is less than D, it is determined that the p-th particle collides with the q-th particle, and the collision force

$${( {f}_{c}^{n} )}_{p q}$$

between the p-th particle and the q-th particle is calculated as follows:

$${( {f}_{c n}^{n} )}_{p q} = - k {d}_{n}^{n} - η {v}_{n}^{n}$$

$${v}_{n}^{n} = ( {v}_{r q}^{n} \cdot \vec{n} ) \vec{n}$$

$${( {f}_{c t}^{n} )}_{pq} = ε {d}_{t}^{n} - η {v}_{t}^{n}$$

$${v}_{t}^{n} = {v}_{r q}^{n} - {v}_{n}^{n}$$

$${( {f}_{c}^{n} )}_{p q} = {( {f}_{c n}^{n} )}_{p q} + {( {f}_{ct}^{n} )}_{p q}$$

where, ε denotes an elastic coefficient; η denotes a viscous dissipation coefficient;

$${d}_{t}^{n}$$

and

$${d}_{n}^{n}$$

denote displacements in the tangential and normal directions, respectively;

$${v}_{r q}^{n}$$

denotes a relative velocity between the p-th and q-th particles;

$${v}_{t}^{n} and {v}_{n}^{n}$$

denote velocities of the p-th particle in the tangential and normal directions, respectively; and \vec{n} denotes a unit normal vector pointing from the center of the p-th particle to a center of the q-th particle.

If the distance between the center of the p-th particle and the wall w is less than D/2, it is determined that the p-th particle collides with the wall w, and the collision force

$${( {f}_{c}^{n} )}_{p w}$$

between the p-th particle and the wall w is calculated as follows:

$${( {f}_{c n}^{n} )}_{p w} = - k {d}_{n}^{n} - η {v}_{n}^{n}$$

$${v}_{n}^{n} = ( {v}_{r w}^{n} \cdot \vec{n} ) \vec{n}$$

$${( {f}_{ct}^{n} )}_{p w} = - ε {d}_{t}^{n} - η {v}_{t}^{n}$$

$${v}_{t}^{n} = {v}_{r w}^{n} - {v}_{n}^{n}$$

$${( {f}_{c}^{n} )}_{p w} = {( {f}_{c n}^{n} )}_{p w} + {( {f}_{c t}^{n} )}_{p w}$$

where,

$${v}_{r w}^{n}$$

denotes a relative velocity between the p-th particle and the wall w; and \vec{n} denotes a unit normal vector pointing vertically from the center of the p-th particle to the wall w.
the total collision force

$${( {F}_{s 2}^{n} )}_{p}$$

experienced by the p-tbh particle at the n-th time is a sum of collision forces between the p-th particle and other particles or walls:

$${( {F}_{s 2}^{n} )}_{p} = {\sum }_{q = 1}^{N - 1} {( {f}_{c}^{n} )}_{pq} + {( {f}_{c}^{n} )}_{pw}$$

C. The particle velocity is solved. Based on a total fluid force and a total collision force experienced by a p-th particle, translational velocity

$${v}_{sp}^{n + 1} ,$$

rotational velocity

$${ω}_{sp}^{n + 1} ,$$

and velocity vector

$${u}_{sp}^{n + 1}$$

of the p-th particle are solved according to Newton's momentum equation and vector angular momentum equation as follows:

$${m}_{sp} \frac{{v}_{sp}^{n + 1} - {v}_{sp}^{n}}{Δ tj} = {( {F}_{s 1}^{n} )}_{p} + {( {F}_{s 2}^{n} )}_{p} \to {v}_{sp}^{n + 1} = {v}_{sp}^{n} + ( {( {F}_{s 1}^{n} )}_{p} + {( {F}_{s 2}^{n} )}_{p} ) \frac{Δ t}{{m}_{sp}}$$

$${I}_{sp} \frac{{ω}_{sp}^{n + 1} - {ω}_{sp}^{n}}{Δ t} = {R}_{sp}^{n} \times ( {( {F}_{s 1}^{n} )}_{p} + {( {F}_{s 2}^{n} )}_{p} ) \to {ω}_{sp}^{n + 1} = {ω}_{sp}^{n} + {R}_{sp}^{n} \times ( {( {F}_{s 1}^{n} )}_{p} + {( {F}_{s 2}^{n} )}_{p} ) \frac{Δ t}{{I}_{sp}}$$

$${u}_{sp}^{n + 1} = {v}_{sp}^{n + 1} + \frac{D}{2} {ω}_{sp}^{n + 1}$$

where, mₛₚ denotes a mass of the p-th particle; lₛₚ denotes an inertia tensor of the p-th particle; and

$${R}_{s}^{n}$$

denotes a radius vector from a center of the p-th particle to a boundary thereof.

D. The steps A to C are repeated to acquire the velocities of all particles, and the velocity vectors of all the particles in the computational domain are acquired, where the fluid force experienced by each grid cell occupied by the particle is denoted as

$${f}_{ibm}^{n} ( x , y ) .$$

S12. The displacement dⁿ⁺¹ and volume fraction

$${∅}_{s}^{n + 1} ( x , y )$$

of the solid particle are solved.

A. The particle displacement is solved.

The velocity vector

$${u}_{sp}^{n + 1}$$

of the p-th particle is decomposed into a horizontal component velocity

$${u}_{spx}^{n + 1}$$

and a vertical component velocity

$${u}_{spy}^{n + 1} .$$

Based on the horizontal component velocity

$${u}_{spx}^{n + 1}$$

and the vertical component velocity

$${u}_{spy}^{n + 1}$$

of the p-th particle, horizontal and velocity vertical displacements of the p-th particle at a subsequent time step Δt are acquired, and a position of the p-th particle at the (n+1)-th time is acquired:

$${x}_{sp}^{n + 1} = {x}_{sp}^{n} + \frac{Δ t}{2} ( {u}_{spx}^{n + 1} + {u}_{spx}^{n} )$$

$${y}_{sp}^{n + 1} = {y}_{sp}^{n} + \frac{Δ t}{2} ( {u}_{spy}^{n + 1} + {u}_{spy}^{n} )$$

$${d}_{p}^{n + 1} = ( {x}_{sp}^{n + 1} , {y}_{sp}^{n + 1} ) - ( {x}_{sp}^{n} , {y}_{sp}^{n} )$$

where,

$${x}_{s p}^{n} and {y}_{s p}^{n}$$

denote horizontal and vertical coordinates of the p-th particle at the n-th time, respectively;

$${u}_{spx}^{n} and {u}_{spy}^{n}$$

denote horizontal and vertical component velocities of the p-th particle at the n-th time, respectively; and

$${d}_{p}^{n + 1}$$

denotes a displacement of the p-th particle from the n-th time to the (n+1)-th time.

B. The solid volume fraction is solved.

If a minimum distance between the grid cell (Nₓ, N_{y}) and the center

$$( {x}_{sp}^{n + 1} , {y}_{s p}^{n + 1} )$$

of the p-th particle is less than D/2, D being the particle size, the volume fraction of the solid particle in the grid cell (Nₓ, N_{y}) at the n-th time is determined as

$${∅}_{s n}^{n + 1} ( x , y ) = 1 .$$

If a maximum distance between the grid cell (Nₓ, N_{y}) and the center

$$( {x}_{sp}^{n + 1} , {y}_{s p}^{n + 1} )$$

of the p-th particle is greater than D/2, the volume fraction of the solid particle in the grid cell (Nₓ, N_{y}) at the n-th time is determined as

$${∅}_{s n}^{n + 1} ( x , y ) = 0 .$$

If the minimum distance between the grid cell (Nₓ, N_{y}) and the center

$$( {x}_{sp}^{n + 1} , {y}_{s p}^{n + 1} )$$

of the p-th particle is greater than D/2 and the maximum distance is less than D/2, it is determined that the grid cell (Nₓ, N_{y}) at the n-th time is at a solid-liquid boundary, and the volume fraction of the grid cell is calculated as follows:

$${∅}_{s n}^{n + 1} ( x , y ) = \frac{1}{2} ( 1 - tanh ( \frac{h}{γ β Δ x} ) )$$

$$β = \vert {\hat{n}}_{s p x}^{n + 1} ( x , y ) \vert + \vert {\hat{n}}_{s p y}^{n + 1} ( x , y ) \vert$$

$$γ = 0. 05 ( 1 - {β}^{2} ) + 0.3$$

where, h denotes a distance from the solid-liquid interface to a center of the grid cell (Nₓ, N_{y}); Δx denotes a grid size;

$${\hat{n}}_{s p x}^{n + 1} ( x , y )$$

denotes a horizontal component of a normal vector

$${\hat{n}}_{s p}^{n + 1} ( x , y )$$

of the solid-liquid interface,

$${\hat{n}}_{s p x}^{n + 1} ( x , y ) = 2 ( x - {x}_{s p}^{n + 1} ) / D ; and {\hat{n}}_{s p {y}^{1}}^{n +} ( x , y )$$

denotes a vertical component of the normal vector

$${\hat{n}}_{sp}^{n + 1} ( x , y )$$

of the solid-liquid interface,

$${\hat{n}}_{spy}^{n + 1} ( x , y ) = 2 ( y - {y}_{s p}^{n + 1} ) / D .$$

C. Based on displacements and solid volume fractions

$${∅}_{s p}^{n + 1} ( x , y )$$

of each particle, the solid volume fraction in the grid cell (Nₓ, N_{y}) of the computational domain at the (n+1)-th time is acquired as follows:

$${ϕ}_{s}^{n + 1} ( x , y ) = {\sum }_{p = 1}^{N} {ϕ}_{s p}^{n + 1} ( x , y )$$

$$If {∅}_{s}^{n + 1} ( x , y ) > 1 , {∅}_{s}^{n + 1} ( x , y ) = 1 .$$

S13. Final velocity uⁿ⁺¹(x, y) of the computational domain at the (n+1)-th time is solved.

According to a relationship between an action force and a reaction force, a force exerted by the particle on the fluid in the grid cell (Nₓ, N_{y}) at the n-th time is defined as

$$- {f}_{i b m}^{n} ( x , y ) ,$$

and based on the force, the fluid velocity at the (n+1)-th time is acquired.

$${u}_{f}^{n + 1} ( x , y ) = {u}_{f}^{F 2} ( x , y ) + {f}_{i b m}^{n} ( x , y ) \cdot Δ t$$

The final velocity uⁿ⁺¹(x, y) of the computational domain as a whole at the (n+1)-th time is solved as follows:

$${u}^{n + 1} ( x , y ) = ( 1 - {∅}_{s}^{n + 1} ( x , y ) ) {u}_{f}^{n + 1} ( x , y ) + {∅}_{s}^{n + 1} ( x , y ) {u}_{s}^{n + 1} ( x , y )$$

S14. A temperature and an interface heat flux density are solved. Specifically:

A. A heat flux density at a particle interface is calculated.

A-1. All solid interface grids

$$( when {∅}_{s}^{n + 1} ( x , y ) ∈ ( 0 , 1 ) )$$

are acquired based on the solid volume fraction

$${∅}_{s}^{n + 1} ( x , y )$$

at the (n+1)-th time, thereby acquiring set

$${H}_{g}^{n + 1} , {H}_{g}^{n + 1} = ( {H}_{1} , {H}_{2} , … {H}_{g} … {H}_{G} ) ,$$

where, H_{g} denotes a g-th interface grid cell in the set

$${H}_{g}^{n + 1} ,$$

and G denotes a total number of interface grid cells in the set

$${H}_{g}^{n + 1} .$$

A-2. A temperature gradient in the interface grid H_{g} is divided in normal direction ((\hat{n}ⁿ⁺¹(H_{g})\hat{n}ⁿ⁺¹(H_{g})·∇ⁿ(H_{g})|ᵢⱼ) and tangential direction ((I−ñⁿ⁺¹(H_{g})\hat{n}ⁿ⁺¹(H_{g}))·∇Tⁿ(H_{g})|ᵢⱼ), where i and j respectively denote numbers of grids in the horizontal and vertical directions; Tⁿ(H_{g}) denotes a temperature in the interface grid H_{g} at the n-th time; \hat{n}ⁿ⁺¹(H_{g}) denotes a unit vector in the normal direction of the particle interface; and I denotes a unit matrix.

A-3. Thermal conductivity coefficients in the normal and tangential directions are calculated, as shown in FIG. 8.

$$\frac{1}{{λ}_{h 1}^{n + 1} ( {H}_{g} )} = \frac{1 - {∅}_{s}^{n + 1} ( {H}_{g} )}{{λ}_{f 1}} + \frac{{∅}_{s}^{n + 1} ( {H}_{g} )}{{λ}_{s}}$$

$${λ}_{a 1}^{n + 1} ( {H}_{g} ) = ( 1 - {∅}_{s}^{n + 1} ( {H}_{g} ) ) {λ}_{f} + {∅}_{s}^{n + 1} ( {H}_{g} ) {λ}_{s}$$

where,

$${λ}_{h 1}^{n + 1} ( {H}_{g} )$$

denotes a thermal conductivity of the interface grid cell H_{g} in the normal direction at the (n+1)-th time;

$${λ}_{a 1}^{n + 1} ( {H}_{g} )$$

denotes a thermal conductivity in the tangential direction at the (n+1)-th time; λₛ denotes a solid thermal conductivity coefficient; and λ_{f} denotes a fluid thermal conductivity coefficient. If the solid interface Fⁿ⁺¹(H_{g})>0, λ_{f} is λ_{f1}. If not, it is λ_{f2}.

A-4. Heat flux

$${q}_{s u r f}^{n + 1} ( {H}_{g} )$$

at the interface grid is calculated as follows:

$${q}_{s u r f}^{n + 1} ( {H}_{g} ) = - {λ}_{h}^{n + 1} ( {H}_{g} ) ( ( {\hat{n}}^{n + 1} ( {H}_{g} ) {\hat{n}}^{n + 1} ( {H}_{g} ) ) \cdot ∇ {T}^{n} ( {H}_{g} ) {\vert}_{i j} ) - {λ}_{a}^{n + 1} ( {H}_{g} ) ( ( I - {\hat{n}}^{n + 1} ( {H}_{g} ) {\hat{n}}^{n + 1} ( {H}_{g} ) ) \cdot ∇ {T}^{n} ( {H}_{g} ) {\vert}_{i j} )$$

B. A heat flux density at a fluid interface is calculated.

B-1. All liquid-liquid interface grids (when Fⁿ⁺¹(x, y)∈(0,1)) are acquired based on the fluid volume fraction Fⁿ⁺¹(x, y) at the (n+1)-th time, thereby acquiring set

$${F}_{h}^{n + 1} , {F}_{h}^{n + 1} = ( {F}_{1} , {F}_{2} , … {F}_{h} … {F}_{H} ) ,$$

where, Fₕ denotes an h-th interface grid cell in the set

$${F}_{h}^{n + 1} ,$$

and H denotes a total number of interface grid cells in the set

$${F}_{h}^{n + 1} .$$

B-2. A temperature gradient in the interface grid Fₕ is divided in normal direction ((\hat{n}ⁿ⁺¹(Fₕ)\hat{n}ⁿ⁺¹(Fₕ))·∇Tⁿ(Fₕ)|ᵢⱼ) and tangential direction ((I−\hat{n}ⁿ⁺¹(Fₕ)\hat{n}ⁿ⁺¹(Fₕ))·∇Tⁿ(Fₕ)|ᵢⱼ), where, i and j respectively denote numbers of grids in the horizontal and vertical directions; T is Tⁿ(Fₕ), denoting a temperature in the interface grid Fₕ at the n-th time; \hat{n}ⁿ⁺¹(Fₕ) denotes a unit vector in the normal direction of the liquid-liquid interface; and I denotes a unit matrix.

B-3. Thermal conductivity coefficients in the normal and tangential directions are calculated, as shown in FIG. 8.

$$\frac{1}{{λ}_{h 2}^{n + 1} ( {F}_{h} )} = \frac{1 - {F}^{n + 1} ( {F}_{h} )}{{λ}_{f 2}} + \frac{{F}^{n + 1} ( {F}_{h} )}{{λ}_{f 1}}$$

$${λ}_{a 2}^{n + 1} ( {F}_{h} ) = ( 1 - {F}^{n + 1} ( {F}_{h} ) ) {λ}_{f 2} + {F}^{n + 1} ( {F}_{h} ) {λ}_{f 1}$$

where,

$${λ}_{h 2}^{n + 1} ( {F}_{h} )$$

denotes a thermal conductivity of the interface grid cell Fₕ in the normal direction at the (n+1)-th time;

$${λ}_{a 2}^{n + 1} ( {F}_{h} )$$

denotes a thermal conductivity in the tangential direction at the (n+1)-th time; and λ_{f1} and λ_{f2} denote the thermal conductivity coefficients of the first fluid and the second fluid, respectively.

B-4. Heat flux

$${q}_{s u r f}^{n + 1} ( {F}_{h} )$$

at the interface grid is calculated as follows:

$${q}_{s u r f}^{n + 1} ( {F}_{h} ) = - {λ}_{h}^{n + 1} ( {F}_{h} ) ( ( {\hat{n}}^{n + 1} ( {F}_{h} ) {\hat{n}}^{n + 1} ( {F}_{h} ) ) \cdot ∇ {T}^{n} ( {F}_{h} ) {\vert}_{i j} ) - {λ}_{a}^{n + 1} ( {F}_{h} ) ( ( I - {\hat{n}}^{n + 1} ( {F}_{h} ) {\hat{n}}^{n + 1} ( {F}_{h} ) ) \cdot ∇ {T}^{n} ( {F}_{h} ) {\vert}_{i j} )$$

C. Temporal update is performed on a diffusion term of an energy equation through a Crack-Nicolson method, and a temperature field is solved in the Euler system.

S15. It is determined whether to terminate a calculation. The steps S03 to S14 are repeated if current number of time steps n<Nₜ, and the calculation is terminated if the current number of time steps n≥Nₜ.

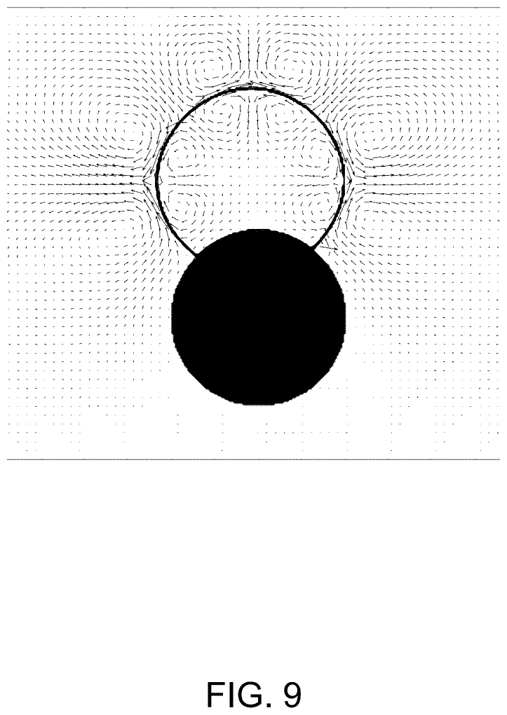

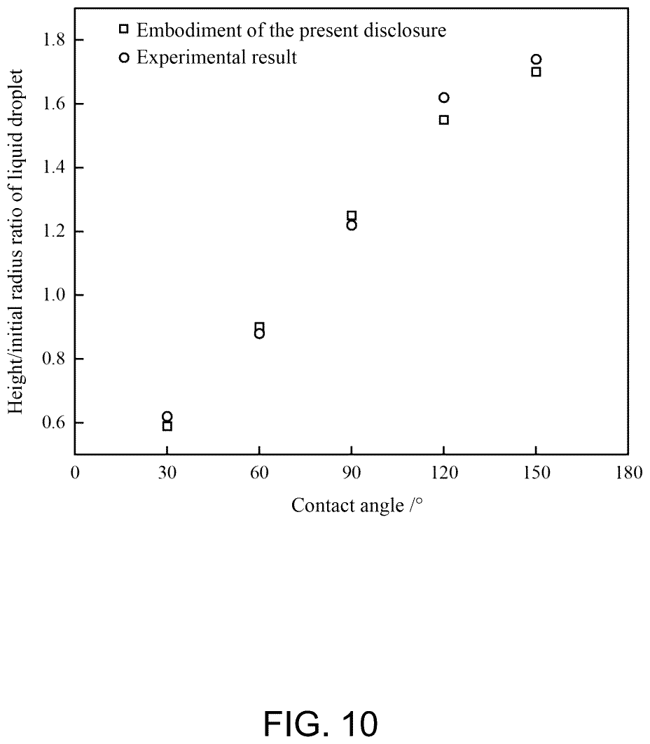

FIG. 9 is a simulation diagram of the liquid droplet colliding with the spherical solid particle in the embodiment of the present disclosure. FIG. 10 shows a comparison between an embodiment and an experiment of the present disclosure on a ratio of a minimum height of the liquid droplet to an initial radius of the liquid droplet after the liquid droplet collides with the spherical solid particle. The contact angles θ are 30°, 60°, 90°, 120°, and 150°, respectively. It can be seen from the figure that the simulation result acquired by the calculation method of the present disclosure has an accuracy of over 98% compared to the experimental result.

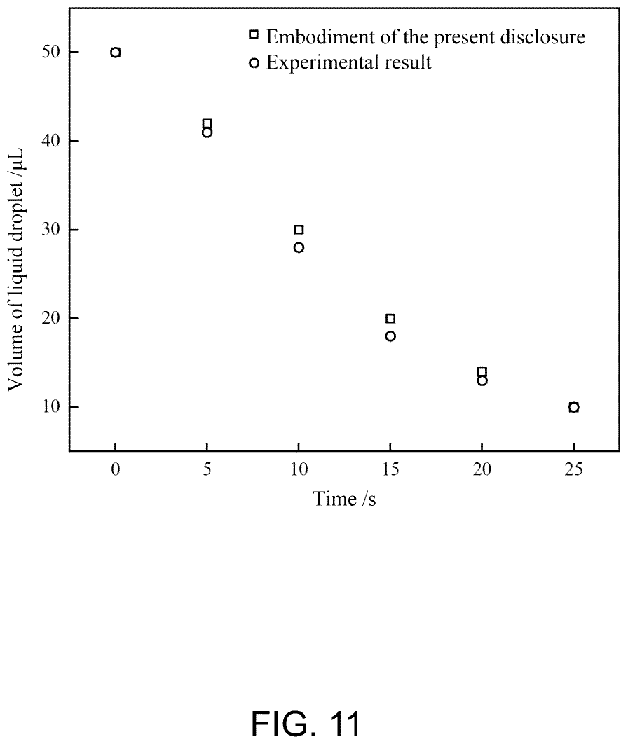

FIG. 11 shows a comparison between an embodiment and an experiment of the present disclosure on a volume variation over time in an evaporation process of the liquid droplet on the solid particle at 120° C. It can be seen from the figure that the accuracy of the heat transfer result acquired by the calculation method of the present disclosure reaches over 97% compared to the experimental result.

A three-phase flow and heat transfer coupled simulation system based on IBM-VOSET-DEM includes a storage medium, where the storage medium is configured to store a program compiled with the three-phase flow and heat transfer coupled simulation method based on IBM-VOSET-DEM.

It should be understood that although this specification is described in accordance with the embodiments, not every embodiment only includes one independent technical solution. This description of the specification is for the sake of clarity only. Those skilled in the art should take the specification as a whole, and the technical solutions in embodiments can also be appropriately combined to form other implementations that can be understood by those skilled in the art.

The series of detailed description listed above are only specific illustration of feasible embodiments of the present disclosure, rather than limiting the claimed scope of the present disclosure. All equivalent embodiments or changes made without departing from the technical spirit of the present disclosure should be included in the claimed scope of the present disclosure.

What is claimed is:

1. A three-phase flow and heat transfer coupled simulation method based on immersed boundary method-volume of fluid and level set-discrete element method (IBM-VOSET-DEM), comprising the following steps:
S01: determining a computational domain, and dividing the computational domain into grids: determining a size of the computational domain, determining a number N of particles and a particle size D in the computational domain, wherein any of the grids in the computational domain is represented as (Nₓ, N_{y}), x∈[1, N₁], y∈[1, N₂]; and setting a calculation time step to Δt and a total number of time steps to Nₜ, wherein N₁ denotes a total number of the grids in a horizontal direction; and N₂ denotes a total number of the grids in a vertical direction;
S02: initializing parameters: determining a fluid velocity
$${u}_{f}^{0} ( x , y )$$
in each grid cell at an initial time, a fluid temperature
$${T}_{f}^{0} ( x , y )$$
in each grid cell at the initial time, and a fluid volume fraction F⁰(x, y) in each grid cell at the initial time; determining a center position (xₛ, yₛ) of each solid particle at the initial time, a solid velocity
$${u}_{s}^{0} ( x , y )$$
in each grid cell at the initial time, a solid temperature
$${T}_{s}^{0} ( x , y )$$
in each grid cell at the initial time, and a solid volume fraction
$${∅}_{s}^{0} ( x , y )$$
in each grid cell at the initial time; and determining all thermophysical parameters, comprising: a density ρ₁ of a first fluid, a density ρ₂ of a second fluid, a density ρₛ of the solid particle, a viscosity μ₁ of the first fluid, a viscosity μ₂ of the second fluid, a thermal conductivity coefficient λ₁ of the first fluid, a thermal conductivity coefficient λ₂ of the second fluid, and a thermal conductivity coefficient λₛ of the solid particle;
S03: reconstructing a liquid-liquid interface:
determining, if a fluid volume fraction Fⁿ(x, y)∈(0,1), that the grid cell (Nₓ, N_{y}) at an n-th time is a liquid-liquid interface grid; determining, if Fⁿ(x, y)=0, that the grid cell (Nₓ, N_{y}) at the n-th time is filled with the second fluid; and determining, if Fⁿ(x, y)=1, that the grid cell (Nₓ, N_{y}) at the n-th time is filled with the first fluid; and
reconstructing, if a grid (x, y) is a liquid-liquid interface grid, an interface shape for each grid cell at the n-th time through a particle line-segment interface calculation (PLIC) method;
S04: determining a fluid volume fraction at an (n+1)-th time:
acquiring, based on a velocity in the grid cell (Nₓ, N_{y}) at the n-th time and the fluid volume fraction Fⁿ(x, y) in the grid cell (Nₓ, N_{y}) at the n-th time, a fluid volume flowing into and out of the grid cell (Nₓ, N_{y}) within a time of Δt, and acquiring the fluid volume fraction Fⁿ⁺¹(x, y) in the grid cell at the (n+1)-th time;
S05: determining a boundary grid; and determining, if the grid (x, y) is a liquid-liquid interface grid, a signed distance function Øⁿ(x, y) of the grid cell (Nₓ, N_{y}) at the n-th time;
S06: determining an interface curvature k(x, y) of an interface grid cell (Nₓ, N_{y});
S07: determining abrupt physical quantities at a smooth interface: determining, by a Heaviside function, a nearby density and viscosity of the smooth interface of the grid cell (Nₓ, N_{y}) at the n-th time:
calculating a smooth density in the grid cell (Nₓ, N_{y}) at the n-th time as follows:
$$ρ ( {∅}^{n} ( x , y ) ) = {ρ}_{1} ( 1 - H ( {∅}^{n} ( x , y ) ) ) + {ρ}_{2} H ( {∅}^{n} ( x , y ) )$$
calculating a smooth viscosity in the grid cell (Nₓ, N_{y}) at the n-th time as follows:
$$μ ( {∅}^{n} ( x , y ) ) = {μ}_{1} ( 1 - H ( {∅}^{n} ( x , y ) ) ) + {μ}_{2} H ( {∅}^{n} ( x , y ) )$$
wherein, the Heaviside function H(Øⁿ) is expressed as follows:
$$H ( {∅}^{n} ( x , y ) ) = \{ \begin{matrix}0 & if {∅}^{n} ( x , y ) < - ϵ \\ \frac{1}{2} [ 1 + \frac{{∅}^{n} ( x , y )}{ϵ} + \frac{1}{π} sin ( \frac{π {∅}^{n} ( x , y )}{ϵ} ) ] & if \vert {∅}^{n} ( x , y ) \vert \leq ϵ \\ 1 & if {∅}^{n} ( x , y ) > ϵ\end{matrix}$$
wherein, ∈ denotes a thickness of the smooth interface;
S08: determining a surface tension of an interface;
calculating the surface tension at the liquid-liquid interface; and specifically, calculating, by a continuous surface force model, a surface tension
$${F}_{s}^{n} ( x , y )$$
in the grid cell (Nₓ, N_{y}) at the n-th time as follows:
$${F}_{s}^{n} ( x , y ) = - σ k ( x , y ) δ ( {∅}^{n} ( x , y ) ) ∇ {∅}^{n} ( x , y )$$
wherein, σ denotes a surface tension coefficient, and
$$δ ( {∅}^{n} ( x , y ) ) = \frac{d H ( {∅}^{n} ( x , y ) )}{d {∅}^{n} ( x , y )}$$
if there is no interface, there is no surface tension; and the surface tension in the grid cell (Nₓ, N_{y}) at the n-th time is
$${F}_{S}^{n} ( x , y ) = 0$$
S09: determining an intermediate fluid velocity
$${u}_{f}^{F 2 , n + 1} ( x , y ) ;$$
S10: repeating the steps S03 to S09 to acquire the fluid volume fraction Fⁿ(x, y) and the intermediate velocity
$${u}_{f}^{F 2 , n + 1} ( x , y )$$
in each grid cell in the computational domain;
S11: determining a particle velocity:
determining, by IBM and DEM methods, respectively, a fluid force
$${F}_{s 1}^{n}$$
and a collision force
$${F}_{s 2}^{n}$$
experienced by the solid particle;
determining the particle velocity: solving, based on a total fluid force and a total collision force experienced by a p-th particle, a translational velocity
$${v}_{sp}^{n + 1} ,$$
a rotational velocity
$${ω}_{sp}^{n + 1} ,$$
and a velocity vector
$${u}_{sp}^{n + 1}$$
of the p-th particle according to Newton's momentum equation and angular momentum equation as follows:
$${m}_{sp} \frac{{v}_{sp}^{n + 1} - {v}_{sp}^{n}}{Δ t} = {( {F}_{s 1}^{n} )}_{p} + {( {F}_{s 2}^{n} )}_{p} \to {v}_{sp}^{n + 1} = {v}_{sp}^{n} + ( {( {F}_{s 1}^{n} )}_{p} + {( {F}_{s 2}^{n} )}_{p} ) \frac{Δ t}{{m}_{sp}} \\ \begin{matrix}{I}_{sp} \frac{{ω}_{sp}^{n + 1} - {ω}_{sp}^{n}}{Δ t} = {R}_{sp}^{n} \times ( {( {F}_{s 1}^{n} )}_{p} + {( {F}_{s 2}^{n} )}_{p} ) \to {ω}_{sp}^{n + 1} \\ = {ω}_{sp}^{n} + {R}_{sp}^{n} \times ( {( {F}_{s 1}^{n} )}_{p} + {( {F}_{s 2}^{n} )}_{p} ) \frac{Δ t}{{I}_{sp}}\end{matrix} \\ {u}_{sp}^{n + 1} = {v}_{sp}^{n + 1} + \frac{D}{2} {ω}_{sp}^{n + 1}$$
wherein, mₛₚ denotes a mass of the p-th particle; lₛₚ denotes an inertia tensor of the p-th particle;
$${R}_{s}^{n}$$
denotes a radius vector from a center of the p-th particle to a boundary of the p-th particle;
$${( {F}_{s 1}^{n} )}_{p}$$
denotes the total fluid force experienced by the p-th particle;
$${( {F}_{s 2}^{n} )}_{p}$$
denotes the total collision force experienced by the p-th particle at the n-th time;
$${v}_{sp}^{n}$$
denotes a translational velocity of the p-th particle at the n-th time; and
$${ω}_{sp}^{n}$$
denotes a rotational velocity of the p-th particle at the n-th time; and
acquiring the particle velocities of all particles, and acquiring the velocity vectors of all the particles in the computational domain, wherein the fluid force experienced by each grid cell occupied by the particle is denoted as
$${f}_{ibm}^{n} ( x , y ) ;$$
S12: determining a displacement dⁿ⁺¹ of the p-th solid particle at the (n+1)-th time and a solid volume fraction
$${∅}_{s}^{n + 1} ( x , y )$$
in the grid cell (Nₓ, N_{y}) at the (n+1)-th time;
S13: determining a final velocity uⁿ⁺¹(x, y) of the computational domain at the (n+1)-th time;
S14: solving a temperature and an interface heat flux density, specifically comprising:
A: calculating a heat flux density at a particle interface:
A-1: acquiring all solid interface grids based on the solid volume fraction
$${∅}_{s}^{n + 1} ( x , y )$$
at the (n+1)-th time, and incorporating all the solid interface grids in a set
$${H}_{g}^{n + 1} ,$$
wherein
$${H}_{g}^{n + 1} = ( {H}_{1} , {H}_{2} , …… {H}_{g} …… {H}_{G} ) ,$$
H_{g} denotes a g-th interface grid cell in the set
$${H}_{g}^{n + 1} ,$$
and G denotes a total number of interface grid cells in the set
$${H}_{g}^{n + 1} ;$$
A-2: dividing a temperature gradient in the interface grid cell H_{g} in a normal direction ((\hat{n}ⁿ⁺¹(H_{g})\hat{n}ⁿ⁺¹(H_{g}))·∇Tⁿ(H_{g})|ᵢⱼ) and a tangential direction ((I−\hat{n}ⁿ⁺¹(H_{g})\hat{n}ⁿ⁺¹(H_{g}))·∇Tⁿ(H_{g})|ᵢⱼ), wherein i and j respectively denote numbers of grids in the horizontal and vertical directions; Tⁿ(H_{g})_{□} denotes a temperature in the interface grid cell H_{g} at the n-th time; \hat{n}ⁿ⁺¹(H_{g}) denotes a unit vector in the normal direction of the particle interface; and I denotes a unit matrix;
A-3: calculating thermal conductivity coefficients in the normal and tangential directions as follows:
$$\frac{1}{{λ}_{h 1}^{n + 1} ( {H}_{g} )} = \frac{1 - {∅}_{s}^{n + 1} ( {H}_{g} )}{{λ}_{f 1}} + \frac{{∅}_{s}^{n + 1} ( {H}_{g} )}{{λ}_{s}}$$
$${λ}_{a 1}^{n + 1} ( {H}_{g} ) = ( 1 - {∅}_{s}^{n + 1} ( {H}_{g} ) ) {λ}_{f} + {∅}_{s}^{n + 1} ( {H}_{g} ) {λ}_{s}$$
wherein,
$${λ}_{h 1}^{n + 1} ( {H}_{g} )$$
denotes a thermal conductivity of the interface grid cell H_{g} in the normal direction at the (n+1)-th time;
$${λ}_{a 1}^{n + 1} ( {H}_{g} )$$
denotes a thermal conductivity in the tangential direction at the (n+1)-th time; λₛ denotes a solid thermal conductivity coefficient; λ_{f} denotes a fluid thermal conductivity coefficient; if the solid interface Fⁿ⁺¹(H_{g})>0, λ_{f} is λ_{f1}; and if not, λ_{f} is λ_{f2};
A-4: calculating a heat flux
$${q}_{surf}^{n + 1} ( {H}_{g} )$$
at the interface grid as follows:
$${q}_{surf}^{n + 1} ( {H}_{g} ) = - {λ}_{h 1}^{n + 1} ( {H}_{g} ) ( ( {\hat{n}}^{n + 1} ( {H}_{g} ) {\hat{n}}^{n + 1} ( {H}_{g} ) ) \cdot ∇ {T}^{n} ( {H}_{g} ) {\vert}_{ij} ) - {λ}_{a 1}^{n + 1} ( {H}_{g} ) ( ( I - {\hat{n}}^{n + 1} ( {H}_{g} ) {\hat{n}}^{n + 1} ( {H}_{g} ) ) \cdot ∇ {T}^{n} ( {H}_{g} ) {\vert}_{ij} )$$
B: calculating a heat flux density at a fluid interface:
B-1: determining all liquid-liquid interface grids based on the fluid volume fraction Fⁿ⁺¹(x, y) at the (n+1)-th time; incorporating all the liquid-liquid interface grids into a set
$${F}_{h}^{n + 1} ,$$
wherein
$${F}_{h}^{n + 1} = ( {F}_{1} , {F}_{2} , … {F}_{h} … {F}_{H} ) ,$$
Fₕ denotes an h-th interface grid cell in the set
$${F}_{h}^{n + 1} ,$$
and H denotes a total number of interface grid cells in the set
$${F}_{h}^{n + 1} ;$$
B-2: dividing a temperature gradient in the interface grid cell Fₕ in a normal direction ((\hat{n}ⁿ⁺¹(Fₕ)\hat{n}ⁿ⁺¹(Fₕ))·∇Tⁿ(Fₕ)|ᵢⱼ) and a tangential direction ((I−\hat{n}ⁿ⁺¹(Fₕ)\hat{n}ⁿ⁺¹(Fₕ))·∇Tⁿ(Fₕ)|ᵢⱼ), wherein i and j respectively denote numbers of grids in the horizontal and vertical directions; Tⁿ(Fₕ)_{□} denotes a temperature in the interface grid cell Fₕ at the n-th time; nⁿ⁺¹(Fₕ) denotes a unit vector in the normal direction of the liquid-liquid interface; and I denotes a unit matrix;
B-3: calculating thermal conductivity coefficients in the normal and tangential directions as follows:
$$\frac{1}{{λ}_{h 2}^{n + 1} ( {F}_{h} )} = \frac{1 - {F}^{n + 1} ( {F}_{h} )}{{λ}_{f 2}} + \frac{{F}^{n + 1} ( {F}_{h} )}{{λ}_{f 1}}$$
$${λ}_{a 2}^{n + 1} ( {F}_{h} ) = ( 1 - {F}^{n + 1} ( {F}_{h} ) ) {λ}_{f 2} + {F}^{n + 1} ( {F}_{h} ) {λ}_{f 1}$$
wherein,
$${λ}_{h 2}^{n + 1} ( {F}_{h} )$$
denotes a thermal conductivity of the interface grid cell Fₕ in the normal direction at the (n+1)-th time;
$${λ}_{a 2}^{n + 1} ( {F}_{h} )$$
denotes a thermal conductivity in the tangential direction at the (n+1)-th time; λ_{f1} and λ_{f2} denote the thermal conductivity coefficients of the first fluid and the second fluid, respectively; and Fⁿ⁺¹(Fₕ) denotes a fluid volume fraction of the h-th interface grid cell at the (n+1)-th time; and
B-4: calculating a heat flux
$${q}_{surf}^{n + 1} ( {F}_{h} )$$
at the interface grid as follows:
$${q}_{surf}^{n + 1} ( {F}_{h} ) = - {λ}_{h 2}^{n + 1} ( {F}_{h} ) ( ( {\hat{n}}^{n + 1} ( {F}_{h} ) {\hat{n}}^{n + 1} ( {F}_{h} ) ) \cdot ∇ {T}^{n} ( {F}_{h} ) {\vert}_{ij} ) - {λ}_{a 2}^{n + 1} ( {F}_{h} ) ( ( I - {\hat{n}}^{n + 1} ( {F}_{h} ) {\hat{n}}^{n + 1} ( {F}_{h} ) ) \cdot ∇ {T}^{n} ( {F}_{h} ) {\vert}_{ij} )$$
C: performing, by a Crack-Nicolson method, temporal update on a diffusion term of an energy equation, and solving a temperature field in an Euler system; and
S15: repeating, if a current number of time steps n<Nₜ, the steps S03 to S14 until the current number of time steps n=Nₜ; wherein
the method is designed to acquire momentum exchanges of a fluid-fluid interface, a fluid-solid interface, and a solid-solid interface, and acquire a nearby heat flux density of the interfaces, thereby more accurately deriving internal flow and heat transfer phenomena of a three-phase system.

2. The three-phase flow and heat transfer coupled simulation method based on the IBM-VOSET-DEM according to claim 1, wherein the reconstructing the interface shape for each grid cell at the n-th time through the PLIC method specifically comprises:
determining, based on the fluid volume fraction Fⁿ(x, y) in the grid cell (Nₓ, N_{y}) at the n-th time, an interface unit normal vector
$$\hat{n} ( x , y ) = \frac{∇ {F}^{n} ( x , y )}{\vert ∇ {F}^{n} ( x , y ) \vert}$$
of the grid cell at the n-th time, wherein ∇ denotes a Hamiltonian operator,
$$∇ = \frac{\partial }{\partial x} i + \frac{\partial }{\partial y} j ;$$
i denotes a horizontal component; j denotes a vertical component; and η denotes a number of time steps, n∈[1, Nₜ]; and
determining, based on the interface unit normal vector \hat{n}(x, y) of the grid cell (Nₓ, N_{y}) at the n-th time and the fluid volume fraction Fⁿ(x, y) in the grid cell (Nₓ, N_{y}) at the n-th time, the interface shape for the grid cell (Nₓ, N_{y}) at the n-th time.

3. The three-phase flow and heat transfer coupled simulation method based on the IBM-VOSET-DEM according to claim 1, wherein the determining the boundary grid and solving the signed distance function Øⁿ(x, y) specifically comprises:
determining, if the fluid volume fraction Fⁿ(x, y) in the grid cell at the n-th time is 0.5, that the grid cell is the boundary grid; and determining all boundary grids of the computational domain;
calculating a minimum distance from the grid cell (Nₓ, N_{y}) to each boundary grid, and acquiring a minimum distance d from the grid cell (Nₓ, N_{y}) to all the boundary grids, specifically, a minimum distance d from the grid cell (Nₓ, N_{y}) to a two-phase interface; and
determining, based on the fluid volume fraction Fⁿ(x, y) in the grid cell (Nₓ, N_{y}) at the n-th time, the signed distance function Øⁿ(x, y) of the grid cell (Nₓ, N_{y}) at the n-th time:
$${∅}^{n} ( x , y ) = \{ \begin{matrix}- d & if {F}^{n} ( x , y ) > 0.5 \\ 0 & if {F}^{n} ( x , y ) = 0.5 \\ d & if {F}^{n} ( x , y ) < 0.5\end{matrix} .$$

4. The three-phase flow and heat transfer coupled simulation method based on the IBM-VOSET-DEM according to claim 3, wherein the determining the interface curvature k(x, y) of the interface grid cell (Nₓ, N_{y}) specifically comprises:
as for the liquid-liquid interface: calculating, based on the signed distance function Øⁿ(x, y) of the grid cell (Nₓ, N_{y}) at the n-th time, the interface curvature k(x, y) as follows:
$$k ( x , y ) = ∇ \cdot \frac{∇ {∅}^{n} ( x , y )}{\vert ∇ {∅}^{n} ( x , y ) \vert} ;$$
determining, if the fluid volume fraction in the grid cell (Nₓ, N_{y}) satisfies Fⁿ(x, y)∈(0,1) and the solid volume fraction satisfies
$${∅}_{s}^{n} ( x , y ) ∈ ( 0 , 1 ) ,$$
that the grid cell (Nₓ, N_{y}) is a three-phase contact cell; and correcting, in case of a three-phase contact, an interface unit normal vector of the grid cell on a contact line based on a contact angle boundary condition according to the following correction equation:
$$( x , y ) = {\hat{n}}_{s} ( x , y ) cos θ + {\hat{t}}_{s} ( x , y ) sin θ$$
wherein, θ denotes a contact angle; \hat{n}ₛ(x, y) denotes a solid wall normal vector of the grid cell (Nₓ, N_{y}); \hat{t}ₛ(x, y) denotes a solid wall tangent vector of the grid cell (Nₓ, N_{y}); and [symbol] (x, y) denotes a corrected interface unit normal vector of the grid cell; and
determining the interface curvature k(x, y) of the grid cell (Nₓ, N_{y}):k(x, y)=∇· [symbol] (x, y).

5. The three-phase flow and heat transfer coupled simulation method based on the IBM-VOSET-DEM according to claim 1, wherein the determining the intermediate fluid velocity
$${u}_{f}^{F 2 , n + 1} ( x , y )$$
specifically comprises:
solving a Navier-Stokes equation based on the velocity, a pressure, and the surface tension in the grid cell (Nₓ, N_{y}) at the n-th time to acquire the intermediate velocity
$${u}_{f}^{F 1 , n + 1} ( x , y )$$
in the grid cell (Nₓ, N_{y}) at the (n+1)-th time, specifically:
$${u}_{f}^{F 1 , n + 1} ( x , y ) = {u}_{f}^{n} ( x , y ) + Δ t ( {A}^{n} ( x , y ) + {B}^{n} ( x , y ) + {F}_{S}^{n} ( x , y ) ) / ρ ( {∅}^{n} ( x , y ) )$$
wherein, Δt denotes the time step; Aⁿ(x, y)=uⁿ(x, y)∇·uⁿ(x, y) denotes a convective term; and Bⁿ(x, y)=μ(Øⁿ(x, y))∇²uⁿ(x, y) denotes a viscosity term; μ(Øⁿ(x, y)) denotes a smooth viscosity of the grid cell (Nₓ, N₂) at the n-th time; and uⁿ(x, y) denotes a final velocity of the computational domain at the n-th time; and
solving, by a fast Fourier transform method, a pressure Poisson equation, to acquire a pressure correction value Pⁿ⁺¹(x, y) of the grid cell (Nₓ, N_{y}) at the (n+1)-th time;
$${∇}^{2} {P}^{n + 1} ( x , y ) = \frac{1}{Δ t} ∇ \cdot {u}_{f}^{F 1 , n + 1} ( x , y ) ;$$
and
correcting, based on the pressure correction value pⁿ⁺¹(x, y) of the grid cell (Nₓ, N_{y}) at the (n+1)-th time, the intermediate velocity
$${u}_{f}^{F 1 , n + 1} ( x , y )$$
in the grid cell (Nₓ, N_{y}) at the (n+1)-th time to acquire a corrected intermediate velocity
$${u}_{f}^{F 2 , n + 1} ( x , y ) ,$$
specifically:
$${u}_{f}^{F 2 , n + 1} ( x , y ) = {u}_{f}^{F 1 , n + 1} ( x , y ) - Δ t ∇ {P}^{n + 1} ( x , y ) .$$

6. The three-phase flow and heat transfer coupled simulation method based on the IBM-VOSET-DEM according to claim 1, wherein the determining, by the IBM and DEM methods, respectively, the fluid force
$${F}_{s 1}^{n}$$
and the collision force
$${F}_{s 2}^{n}$$
experienced by the solid particle specifically comprises:
determining, by the IBM method, the fluid force
$${F}_{s 1}^{n}$$
experienced by the solid particle:
determining the fluid force experienced by the p-th particle at the n-th time through vector summation on fluid forces experienced by grids occupied by the p-th particle; determining a set
$${Q}_{p}^{n}$$
of all grid cells occupied by the p-th particle based on a center position and a radius of the p-th particle at the n-th time, wherein
$${Q}_{p}^{n} = ( {P}_{1} , {P}_{2} … {P}_{e} … {P}_{E} ) ,$$
Pₑ denotes an e-th grid cell in the set
$${Q}_{p}^{n} ;$$
and E denotes a total number of grid cells in the set
$${Q}_{p}^{n} ;$$
solving, by the IBM method, a fluid force
$${f}_{ibmi}^{n} ( {P}_{e} )$$
experienced by the grid cell Pₑ in the set Q_{P}, wherein the method also allows a solid-liquid interface to satisfy a non-slip boundary condition, specifically:
the fluid force experienced by the grid cell P_e at the n-th time
$${f}_{ibmi}^{n} ( {P}_{e} ) = \frac{{ϕ}_{s}^{n} ( {P}_{e} ) ( {u}_{s}^{n} ( {P}_{e} ) - {u}_{f}^{F 2 , n + 1} ( {P}_{e} ) )}{Δ t}$$
wherein:
$${u}_{f}^{F 2 , n + 1} ( {P}_{e} )$$
denotes an intermediate velocity in the grid cell Pₑ at the (n+1)-th time;
$${u}_{s}^{n} ( {P}_{e} )$$
denotes a solid velocity in the grid cell Pₑ at the n-th time; and
$${∅}_{s}^{n} ( {P}_{e} )$$
denotes a volume fraction of the solid particle in the grid cell Pₑ at the n-th time;
acquiring the fluid force experienced by each grid cell in the set at the n-th time,
$${Q}_{p}^{n}$$
at the n-th time, specifically, the fluid force experienced by each grid cell occupied by the p-th particle at the n-th time; and acquiring, by summation, the total fluid force
$${( {F}_{s 1}^{n} )}_{p}$$
experienced by the p-th particle:
$${( {F}_{s 1}^{n} )}_{p} = {\sum }_{e = 1}^{E} {f}_{ibmi}^{n} ( {P}_{e} )$$
wherein,
$${( {F}_{s 1}^{n} )}_{p}$$
denotes the total fluid force experienced by the p-th particle; and determining, by the DEM method, the collision force
$${F}_{s 2}^{n}$$
experienced by the solid particle:
determining a set
$${Q}_{q}^{n}$$
of particles other than the p-th particle, wherein
$${Q}_{q}^{n} = ( {Q}_{1} , {Q}_{2} … {Q}_{q} … {Q}_{N - 1} ) ,$$
Q_{q} denotes a q-th particle in the set
$${Q}_{q}^{n} ;$$
and N denotes a number of particles in the computational domain;
determining a set
$${Q}_{w}^{n}$$
of walls, wherein w denotes different walls, and w=1, 2, 3, 4;
solving, by a DEM soft ball collision model, a collision force
$${( {f}_{c}^{n} )}_{pq}$$
between the p-th particle and the q-th particle at the n-th time and a collision force
$${( {f}_{c}^{n} )}_{pw}$$
between the p-th particle and a wall w at the n-th time:
if a center distance between the p-th particle and the q-th particle is greater than D: determining that the p-th particle does not collide with the q-th particle, specifically, the collision force
$${( {f}_{c}^{n} )}_{pq}$$
between the p-th particle and the q-th particle at the n-th time is 0;
if a distance between a center of the p-th particle and the wall w is greater than D/2: determining that the p-th particle does not collide with the wall w, specifically, the collision force
$${( {f}_{c}^{n} )}_{p w}$$
between the p-th particle and the wall w at the n-th time is 0;
if the center distance between the p-th particle and the q-th particle is less than D: determining that the p-th particle collides with the q-th particle, and calculating the collision force
$${( {f}_{c}^{n} )}_{p q}$$
between the p-th particle and the q-th particle as follows:
$${( {f}_{c n}^{n} )}_{p q} = - k {d}_{n}^{n} - η {v}_{n}^{n}$$
$${v}_{n}^{n} = ( {v}_{r q}^{n} \cdot \vec{n} ) \vec{n}$$
$${( {f}_{ct}^{n} )}_{p q} = - ε {d}_{t}^{n} - η {v}_{t}^{n}$$
$${v}_{t}^{n} = {v}_{r q}^{n} - {v}_{n}^{n}$$
$${( {f}_{c}^{n} )}_{p q} = {( {f}_{c n}^{n} )}_{p q} + {( {f}_{ct}^{n} )}_{p q}$$
wherein, ε denotes an elastic coefficient; η denotes a viscous dissipation coefficient;
$${d}_{t}^{n} and {d}_{n}^{n}$$
denote displacements in the tangential and normal directions, respectively;
$${v}_{r q}^{n} {d}_{t}^{n} and {d}_{n}^{n}$$
denotes a relative velocity between the p-th and q-th particles;
$${v}_{t}^{n} and {v}_{n}^{n}$$
denote velocities of the p-th particle in the tangential and normal directions, respectively; \vec{n} denotes a unit normal vector pointing from the center of the p-th particle to a center of the q-th particle;
$${( {f}_{cn}^{n} )}_{pq}$$
denotes a collision force of the p-th particle and the q-th particle in the normal direction; and
$${( {f}_{ct}^{n} )}_{pq}$$
denotes a collision force of the p-th particle and the q-th particle in the tangential direction;
if the distance between the center of the p-th particle and the wall w is less than D/2: determining that the p-th particle collides with the wall w, and calculating the collision force
$${( {f}_{c}^{n} )}_{pw}$$
between the p-th particle and the wall w as follows:
$${( {f}_{c n}^{n} )}_{p w} = - k {d}_{n}^{n} - η {v}_{n}^{n}$$
$${v}_{n}^{n} = ( {v}_{r w}^{n} \cdot \vec{n} ) \vec{n}$$
$${( {f}_{ct}^{n} )}_{p w} = - ε {d}_{t}^{n} - η {v}_{t}^{n}$$
$${v}_{t}^{n} = {v}_{r w}^{n} - {v}_{n}^{n}$$
$${( {f}_{c}^{n} )}_{p w} = {( {f}_{c n}^{n} )}_{p w} + {( {f}_{ct}^{n} )}_{p w}$$
wherein,
$${v}_{r w}^{n}$$
denotes a relative velocity between the p-th particle and the wall w; and \vec{n} denotes a unit normal vector pointing vertically from the center of the p-th particle to the wall w;
the total collision force
$${( {F}_{s 2}^{n} )}_{p}$$
experienced by the p-th particle at the n-th time is a sum of collision forces between the p-th particle and other particles or walls:
$${( {F}_{s 2}^{n} )}_{p} = {\sum }_{q = 1}^{N - 1} {( {f}_{c}^{n} )}_{p q} + {( {f}_{c}^{n} )}_{p w} .$$

7. The three-phase flow and heat transfer coupled simulation method based on the IBM-VOSET-DEM according to claim 6, wherein the determining the displacement dⁿ⁺¹ of the p-th solid particle at the (n+1)-th time specifically comprises:
decomposing the velocity vector
$${u}_{s p}^{n + 1}$$
of the p-th particle into a horizontal component velocity
$${u}_{s p x}^{n + 1}$$
and a vertical component velocity
$${u}_{spy}^{n + 1} ;$$
and calculating, based on the horizontal component velocity
$${u}_{spx}^{n + 1}$$
and the vertical component velocity of
$${u}_{spy}^{n + 1}$$
of the p-th particle, horizontal and vertical displacements of the p-th particle at a subsequent time step Δt, and acquiring a position of the p-th particle at the (n+1)-th time:
$${x}_{sp}^{n + 1} = {x}_{sp}^{n} + \frac{Δ t}{2} ( {u}_{spx}^{n + 1} + {u}_{spx}^{n} )$$
$${y}_{sp}^{n + 1} = {y}_{sp}^{n} + \frac{Δ t}{2} ( {u}_{spy}^{n + 1} + {u}_{spy}^{n} )$$
$${d}_{p}^{n + 1} = ( {x}_{sp}^{n + 1} , {y}_{sp}^{n + 1} ) - ( {x}_{sp}^{n} , {y}_{sp}^{n} )$$
wherein,
$${x}_{sp}^{n} and {y}_{sp}^{n}$$
denote horizontal and vertical coordinates of the p-th particle at the n-th time, respectively;
$${u}_{spx}^{n} and {u}_{spy}^{n}$$
denote horizontal and vertical component velocities of the p-th particle at the n-th time, respectively; and
$${d}_{p}^{n + 1}$$
denotes a displacement of the p-th particle from the n-th time to the (n+1)-th time,
$${x}_{sp}^{n + 1}$$
denotes a horizontal coordinate of the p-th particle at the (n+1)-th time; and
$${y}_{sp}^{n + 1}$$
denotes a vertical coordinate of the p-th particle at the (n+1)-th time.

8. The three-phase flow and heat transfer coupled simulation method based on the IBM-VOSET-DEM according to claim 6, wherein the determining the solid volume fraction
$${∅}_{s}^{n + 1} ( x , y )$$
in the grid cell (Nₓ, N_{y}) at the (n+1)-th time specifically comprises:
if a minimum distance between the grid cell (Nₓ, N_{y}) and the center
$$( {x}_{sp}^{n + 1} , {y}_{sp}^{n + 1} )$$
of the p-th particle is less than D/2: determining the volume fraction of the solid particle in the grid cell (Nₓ, N_{y}) at the n-th time as
$${∅}_{sn}^{n + 1} ( x , y ) = 1 ,$$
wherein
$${x}_{sp}^{n + 1}$$
denotes a horizontal coordinate of the p-th particle at the (n+1)-th time; and
$${y}_{sp}^{n + 1}$$
denotes a vertical coordinate of the p-th particle at the (n+1)-th time;
if a maximum distance between the grid cell (Nₓ, N_{y}) and the center
$$( {x}_{sp}^{n + 1} , {y}_{sp}^{n + 1} )$$
of the p-th particle is greater than D/2: determining the volume fraction of the solid particle in the grid cell (Nₓ, N_{y}) at the n-th time as
$${∅}_{sn}^{n + 1} ( x , y ) = 0 ;$$
if the minimum distance between the grid cell (Nₓ, N_{y}) and the center
$$( {x}_{sp}^{n + 1} , {y}_{sp}^{n + 1} )$$
of the p-th particle is greater than D/2 and the maximum distance is less than D/2: determining that the grid cell (Nₓ, N_{y}) at the n-th time is at a solid-liquid boundary, and calculating the volume fraction of the grid cell as follows:
$${∅}_{sn}^{n + 1} ( x , y ) = \frac{1}{2} ( 1 - tanh ( \frac{h}{γβΔ x} ) )$$
$$β = \vert {\hat{n}}_{spx}^{n + 1} ( x , y ) \vert + \vert {\hat{n}}_{spy}^{n + 1} ( x , y ) \vert$$
$$γ = 0.05 ( 1 - {β}^{2} ) + 0.3$$
wherein, h denotes a distance from the solid-liquid interface to a center of the grid cell (Nₓ, N_{y}); Δx denotes a grid size;
$${\hat{n}}_{spx}^{n + 1} ( x , y )$$
denotes a horizontal component of a normal vector
$${\hat{n}}_{sp}^{n + 1} ( x , y )$$
of the solid-liquid interface,
$${\hat{n}}_{spx}^{n + 1} ( x , y ) = 2 ( x - {x}_{sp}^{n + 1} ) / D ;$$
$$and {\hat{n}}_{spy}^{n + 1} ( x , y )$$
denotes a vertical component of the normal vector
$${\hat{n}}_{sp}^{n + 1} ( x , y )$$
of the solid-liquid interface,
$${\hat{n}}_{spy}^{n + 1} ( x , y ) = 2 ( y - {y}_{sp}^{n + 1} ) / D ;$$
determining, based on the displacement and solid volume fraction
$${∅}_{sp}^{n + 1} ( x , y )$$
each particle, the solid volume fraction
$${∅}_{s}^{n + 1} ( x , y )$$
in the grid cell (Nₓ, N_{y}) of the computational domain at the (n+1)-th time:
$${ϕ}_{s}^{n + 1} ( x , y ) = {\sum }_{p = 1}^{N} {ϕ}_{sp}^{n + 1} ( x , y )$$
$$if {∅}_{s}^{n + 1} ( x , y ) > 1 , {∅}_{s}^{n + 1} ( x , y ) = 1.$$

9. The three-phase flow and heat transfer coupled simulation method based on the IBM-VOSET-DEM according to claim 6, characterized in that wherein the determining the final velocity uⁿ⁺¹(x, y) of the computational domain at the (n+1)-th time specifically comprises:
defining a force exerted by the particle on the fluid in the grid cell (Nₓ, N_{y}) at the n-th time as
$$- {f}_{ibm}^{n} ( x , y ) ;$$
and acquiring, based on
$$- {f}_{ibm}^{n} ( x , y ) ,$$
the fluid velocity at the (n+1)-th time as follows:
the fluid velocity at the (n+1)-th time
$${u}_{f}^{n + 1} ( x , y ) = {u}_{f}^{F 2 , n + 1} ( x , y ) + {f}_{ibm}^{n} ( x , y ) \cdot Δ t ;$$
and
determining the final velocity uⁿ⁺¹(x, y) of the computational domain as a whole at the (n+1)-th time as follows:
$${u}^{n + 1} ( x , y ) = ( 1 - {∅}_{s}^{n + 1} ( x , y ) ) {u}_{f}^{n + 1} ( x , y ) + {∅}_{s}^{n + 1} ( x , y ) {u}_{sp}^{n + 1} ( x , y ) .$$

10. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 1.

11. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 2.

12. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 3.

13. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 4.

14. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 5.

15. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 6.

16. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 7.

17. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 8.

18. A three-phase flow and heat transfer coupled simulation system based on IBM-VOSET-DEM, characterized by comprising a storage medium, wherein the storage medium is configured to store a program compiled with the three-phase flow and heat transfer coupled simulation method based on the IBM-VOSET-DEM according to claim 9.
